(19) United States
(12) Patent Application Publication
(10) Pub. No.: US 2024/0021758 A1
(43) Pub. Date: Jan. 18, 2024

(54) DISPLAY PANEL AND METHOD FOR FORMING THE SAME, AND DISPLAY APPARATUS

(71) Applicant: Hubei Yangtze Industrial Innovation Center Of Advanced Display Co., Ltd., Wuhan (CN)

(72) Inventors: Xiaoli LIU, Wuhan (CN); Cao LIU, Wuhan (CN); Sitao HUO, Wuhan (CN)

(73) Assignee: Hubei Yangtze Industrial Innovation Center Of Advanced Display Co., Ltd., Wuhan (CN)

(21) Appl. No.: 17/976,747

(22) Filed: Oct. 28, 2022

(30) Foreign Application Priority Data
Jul. 18, 2022 (CN) 202210843228.1

(51) Int. Cl. H01L 33/38; H01L 33/62; H01L 33/00

(52) U.S. Cl. CPC H01L 33/382; H01L 33/62; H01L 33/005; H01L 2933/0016; H01L 2933/0066

(57) ABSTRACT

Embodiments of the present invention provide a display panel, a method for forming the display panel, and a display apparatus. The display panel includes: a drive substrate and a light emitting element. The drive substrate includes a first film layer. The first film layer is provided with an opening. The light emitting element is positioned on the drive substrate. The light emitting element includes a body portion and an electrode, and the electrode of the light emitting element includes a first portion positioned in the opening for improving the reflectivity of the display panel.

### CROSS-REFERENCE TO RELATED APPLICATION

This application claims priority to Chinese Patent Application No. 202210843228.1, filed on Jul. 18, 2022, which is hereby incorporated by reference in its entirety.

### TECHNICAL FIELD

The present application relates to the field of display technology, and in particular, to a display panel, a method for forming the display panel, and a display apparatus.

### BACKGROUND

A light emitting diode (LED) has advantages of fast response speed, high luminous brightness and long service life, and is demanded in many applications. Light emitting diode display panels have always been a research and development hotspot.

Light emitting diode display panels are fabricated by transferring light emitting diodes to target substrates and bonding the light emitting diodes to the target substrates.

Currently, the light emitting diode display panels have a problem of high reflectivity, which needs to be solved urgently.

### SUMMARY

In view of this, embodiments of the present invention provide a display panel, a method for forming a display panel, and a display apparatus, so as to solve the problem of high reflectivity of the display panel.

Embodiments of the present invention provide a display panel including a drive substrate and a light emitting element, where the drive substrate includes a first film layer, and the first film layer is provided with an opening; the light emitting element is positioned on the drive substrate, the light emitting element includes a body portion and an electrode, and the electrode includes a first portion positioned in the opening.

The method for forming the display panel according to embodiments of the present invention includes the following steps:
forming a first film layer of a drive substrate, the first film layer being provided with an opening;
forming a photoresist layer, the photoresist layer being positioned on a side of the first film layer;
forming a photoresist pattern, the photoresist pattern having a through hole overlapped with the opening;
forming an electrode layer, the electrode layer comprising a first electrode portion and a second electrode portion, the first electrode portion covering the photoresist pattern, and the second electrode portion comprising a portion positioned in the opening;
removing the photoresist pattern and the first electrode portion;
providing a light emitting element and transferring the light emitting element over the drive substrate, where the light emitting element comprises a body portion and a bonding electrode;
bonding the light emitting element to the second electrode portion, so that the bonding electrode and the second electrode portion form an electrode of the light emitting element.

Embodiments of the present invention provide a display apparatus including the display panel according to any one of the embodiments of the present invention.

Compared with the prior art, the display panel, the method for forming the display panel and the display apparatus according to the embodiments of the present invention have at least the following beneficial technical effects.

By arranging the electrode of the light emitting element at least partially in the opening of the first film layer, the metal wired electrode in the related art can be removed, the reflectivity of the display panel can be reduced, and the display effect of the display panel can be improved.

### BRIEF DESCRIPTION OF THE DRAWINGS

FIG. 1 is a top view of a display panel according to an embodiment of the present invention.

FIG. 2 is an enlarged schematic view of a part of a display area in FIG. 1.

FIG. 3 is a sectional schematic view along the line AA′ in FIG. 2.

FIG. 4 is an enlarged schematic view of a part in FIG. 3.

FIG. 5 is another enlarged schematic view of a part in FIG. 3.

FIG. 6 is a flowchart of a method for forming a display panel according to an embodiment of the present invention.

FIG. 7 is a partial top view of a drive substrate according to an embodiment of the present invention.

FIG. 8 is a sectional schematic view along the line BB′ in FIG. 7.

FIG. 9 is another sectional schematic view along the line BB′ in FIG. 7.

FIG. 10 is a partial top view after forming a photoresist layer on the drive substrate.

FIG. 11 is a sectional schematic view along the line CC′ in FIG. 10.

FIG. 12 is a schematic structural view of patterning the photoresist layer.

FIG. 13 is a schematic structural view after forming an electrode layer.

FIG. 14 is a comparison view of FIG. 13.

FIG. 15 is a schematic structural view after removing the photoresist pattern.

FIG. 16 is a schematic view of transferring a light emitting element.

FIG. 17 is a schematic structural view of a bonding process of a light emitting element and a drive substrate.

FIG. 18 is another schematic view of transferring a light emitting element.

FIG. 19 is another sectional schematic view along the line AA′ in FIG. 2.

FIG. 20 is another schematic structural view of patterning the photoresist layer.

FIG. 21 is a partial top view of a first organic layer.

FIG. 22 is another sectional schematic view along the line AA′ in FIG. 2.

FIG. 23 is another sectional schematic view along the line AA′ in FIG. 2.

FIG. 24 is a schematic structural view of the process of forming a first film layer, forming an electrode layer and removing a part of the electrode.

FIG. 25 is another sectional schematic view along the line AA′ in FIG. 2.

FIG. 26 is a schematic structural view of a first film layer according to an embodiment of the present invention.

FIG. 27 is another sectional schematic view along the line AA′ in FIG. 2.

FIG. 28 and FIG. 29 are respectively another enlarged schematic view of a part of the display area in FIG. 1.

FIG. 30 and FIG. 31 are respectively enlarged schematic views of a region A1 in FIG. 28 and FIG. 29.

FIG. 32 and FIG. 33 are respectively enlarged schematic views of a region A2 in FIG. 28 and FIG. 29.

FIG. 34 and FIG. 35 are respectively enlarged schematic views of a region A3 in FIG. 28 and FIG. 29.

FIG. 36 to FIG. 39 are respectively sectional schematic views along the line DD′ in FIG. 28 and FIG. 29.

FIG. 40 is a sectional schematic view along the line EE′ in FIG. 29.

FIG. 41 to FIG. 43 are respectively sectional schematic views along the line DD′ in FIG. 28 and FIG. 29.

FIG. 44 is an enlarged schematic view of a region A4 in FIG. 29.

FIG. 45 is a schematic view of a display apparatus according to an embodiment of the present application.

### DETAILED DESCRIPTION

In order to make the objects, technical solutions and advantages of the embodiments of the present application clearer, the technical solutions in the embodiments of the present application will be described clearly and completely in conjunction with the drawings in the embodiments of the present application. Obviously, the described embodiments are a part of the embodiments of the present application, but not all of the embodiments. Based on the embodiments in the present application, all other embodiments obtained by those ordinary skilled in the art without any creative work shall fall within the protection scope of the present application.

In this application, parts with same reference numerals can be referred to each other in the corresponding text description part of the related drawings.

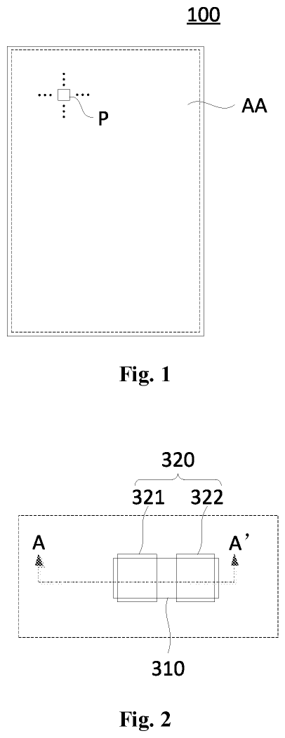

FIG. 1 is a top view of a display panel according to an embodiment of the present invention. As shown in FIG. 1, a display panel 100 includes a display area AA. A plurality of pixels P are arranged in the display area AA in regular pattern. The plurality of pixels P are configured for displaying images.

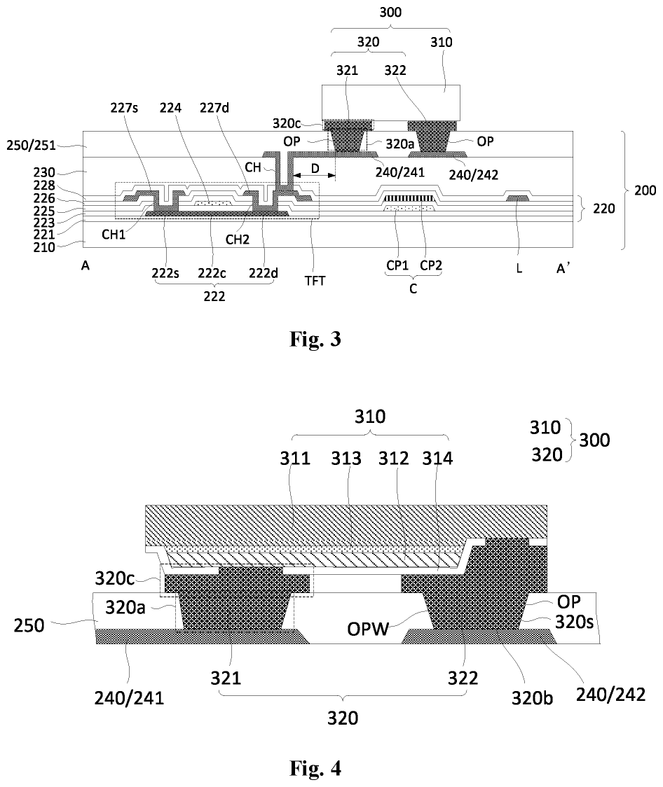

FIG. 2 is a schematic enlarged view of a part of a display area in FIG. 1. FIG. 3 is a schematic sectional view taken along line AA′ in FIG. 2. As shown in FIG. 2 and FIG. 3, the display panel includes a drive substrate 200 and a light emitting element 300.

The drive substrate 200 may include a substrate 210 and a drive circuit layer 220. The drive circuit layer 220 is positioned on the substrate 210.

The substrate 210 may be an insulation substrate. As an example, the substrate 210 may include materials such as glass, quartz, and polymer resins. Herein, the polymer material may include polyethersulfone (PES), polyacrylate (PA), polyarylate (PAR), polyetherimide (PEI), polyethylene naphthalate (PEN), polyethylene Ethylene terephthalate (PET), polyphenylene sulfide (PPS), polyallylate, polyimide (PI), polycarbonate (PC), cellulose triacetate (CAT), cellulose acetate propionate (CAP) or a combination thereof. As another example, the substrate 210 may be a flexible substrate including polyimide (PI).

The drive circuit layer 220 may include a structures such as a thin film transistor TFT, a capacitor C, and a wiring L.

As an example, a film layer of the drive circuit layer 220 may include a buffer layer 221, an active pattern 222, a gate insulation layer 223, a gate 224, an intermediate dielectric layer 225, an interlayer dielectric layer 226, a source 227s, a drain 227d and a passivation layer 228.

The buffer layer 221 may prevent impurities such as oxygen and moisture from permeating from the substrate 210, and may planarize the substrate 210. In addition, the buffer layer 221 may control a heat transfer rate in the annealing process for the formation of the active pattern 222. The buffer layer 221 may include a stacked structure composed of one or more of the inorganic materials such as silicon oxide, silicon nitride, and silicon oxynitride.

The active pattern 222 may be arranged on the buffer layer 221. The active pattern 222 may include a channel area 222c, a source area 222s and a drain area 222d at opposite ends of the channel area 222c. Taking the active pattern 222 including polysilicon semiconductor as an example, the channel area 222c includes undoped polysilicon semiconductor, and the source area 222s and the drain area 222d may include polysilicon semiconductor doped with an impurity. The active pattern 222 may be an n-type semiconductor or a p-type semiconductor. As an example, the impurity doped in the source area 222s and the drain area 222d may be an n-type impurity, for example, a material such as phosphorus (P) ions may be used as the n-type impurity. As an example, the impurity doped in the source area 222s and the drain area 222d may be a p-type impurity. For example, a material such as boron (B) ions may be used as p-type impurity.

The active pattern 222 may include a silicon semiconductor or an oxide semiconductor.

The silicon semiconductor may include one or more of amorphous silicon, single monocrystalline silicon, and polycrystalline silicon. As an example, the active pattern 222 may include low temperature polycrystalline silicon.

The oxide semiconductor may include indium (In), zinc (Zn), gallium (Ga), tin (Sn), titanium (Ti), aluminum (Al), hafnium (Hf), zirconium (Zr), magnesium (Mg), and the like. The active pattern 212 may include a binary compound, a ternary compound or a quaternary compound. For example, the active pattern 212 may include indium gallium zinc oxide (IGZO), indium tin zinc oxide (ITZO), gallium zinc oxide (GaZnxOy), Indium Zinc Oxide (IZO), Zinc Magnesium Oxide (ZnMgxOy), Zinc Oxide (ZnOx), Gallium Oxide (GaOx), Tin Oxide (SnOx), Indium Oxide (InOx), Indium Gallium Hafnium Oxide (IGHO), Tin Aluminum Zinc Oxide (TAZO), Indium Gallium Tin Oxide (IGTO), and the like. These materials may be used alone, or may be used in combination with each other. In an exemplary embodiment of the present disclosure, the above-mentioned oxide semiconductor may be doped with lithium (Li), sodium (Na), manganese (Mn), nickel (Ni), palladium (Pd), copper (Cu), carbon (C), Nitrogen (N), phosphorus (P), titanium (Ti), zirconium (Zr), vanadium (V), ruthenium (Ru), germanium (Ge), tin (Sn), fluorine (F), and the like.

The gate insulation layer 223 covers the active pattern 222. The gate insulation layer 223 may be arranged on the buffer layer 221. The gate insulation layer 223 may include a stacked structure composed of one or more of inorganic materials such as silicon oxide, silicon nitride, and silicon oxynitride, and the like.

The gate 224 may be arranged on the gate insulation layer 223 and may be overlapped with the channel area 222c of the active pattern 222. The gate 224 and the active pattern 222 may form a thin film transistor TFT. The gate 224 may include metals such as aluminum (Al), silver (Ag), chromium (Cr), titanium (Ti), tantalum (Ta), molybdenum (Mo), and the like; alloys thereof; nitrides thereof; conductive metal oxides; transparent conductive materials; and the like. As an example, the gate 224 may include molybdenum (Mo).

The intermediate dielectric layer 225 covers the gate 224 and may be arranged on the gate insulation layer 223. The intermediate dielectric layer 225 may include a stacked structure composed of one or more of the inorganic materials such as silicon oxide, silicon nitride, silicon oxynitride, and the like. As an example, the intermediate dielectric layer 225 may include silicon nitride.

The interlayer dielectric layer 226 may be arranged on the intermediate dielectric layer 225. The interlayer dielectric layer 226 may include a stacked structure composed of one or more of the inorganic materials such as silicon oxide, silicon nitride, silicon oxynitride, and the like.

The source 227s may be in contact with the source area 222s of the active pattern 222, and the drain 227d may be in contact with the drain area 222d of the active pattern 222. The source 227s and the drain 227d may be formed in a same process, and both are positioned in a same film. As an example, a first contact via CH1 exposing a part of the source area 222s and a second contact via CH2 exposing a part of the drain area 222d may be each formed through the gate insulation layer 223, the intermediate dielectric layer 225 and the interlayer dielectric layer 226. The source 227s may contact an upper surface of the source area 222s through the first contact via CH1, and the drain 227d may contact an upper surface of the drain area 222d through the second contact via CH2. The source 227s and the drain 227d may include metals such as aluminum (Al), silver (Ag), chromium (Cr), titanium (Ti), tantalum (Ta), molybdenum (Mo), and the like; alloys thereof; nitrides thereof; conductive metal oxides; transparent conductive materials; and the like. As an example, the source 227s and the drain 227d may include a Ti/Ai/Ti metal stacked structure.

The passivation layer 228 covers the source 227s and the drain 227d, and the passivation layer 228 may be arranged on the interlayer dielectric layer 226. The passivation layer 228 may include a stacked structure composed of one or more of inorganic materials such as silicon oxide, silicon nitride, silicon oxynitride, and the like. As an example, the passivation layer 228 may include silicon nitride.

A capacitor C may include a first electrode plate CP1 and an opposite second electrode plate CP2. The capacitor C may be configured to maintain the node potential in the drive circuit. The first electrode plate CP1 may be positioned between the gate insulation layer 223 and the intermediate dielectric layer 225, may be positioned in the same film layer as the gate 224, and may be formed of a same material as the gate 224. The second electrode plate CP2 may be positioned between the intermediate dielectric layer 225 and the interlayer dielectric layer 226. The second electrode plate CP2 may include metals such as aluminum (Al), silver (Ag), chromium (Cr), titanium (Ti), tantalum (Ta) and molybdenum (Mo); alloys thereof; nitrides thereof; conductive metal oxides; transparent conductive materials; and the like. As an example, the second electrode plate CP2 may include molybdenum (Mo).

The wiring L may be configured to provide various signals. In FIG. 3, the wiring L being positioned between the interlayer dielectric layer 226 and the passivation layer 228 is taken as an example. The wiring L may be positioned in a same film layer as the source 227s and the drain 227d, and may be formed of a same material as the source 227s and the drain 227d. According to the type and requirements of a signal transmitted by the wiring L, the wiring L may be positioned in another film layer or multiple film layers, for example, the wiring L and the gate 224 are positioned in a same film layer; or the wiring L and the second electrode plate CP2 may be positioned in a same film layer; or the like.

The drive circuit layer 220 includes a drive circuit for driving the light emitting element 300 to emit light. As an example, the drive circuit includes a pixel circuit electrically connected to the light emitting element 300 for driving the light emitting element 300 to emit light.

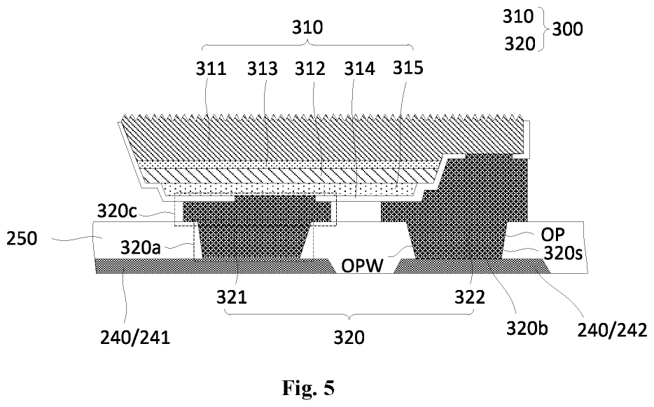

FIG. 4 is a schematic enlarged view of a part in FIG. 3. FIG. 5 is another schematic enlarged view of a part in FIG. 3. Only some of the film layers of the drive substrate 200 are illustrated in FIG. 4 and FIG. 5.

As shown in FIG. 3 to FIG. 5, the light emitting element 300 may be a light emitting diode, for example, an inorganic light emitting diode. The size of the light emitting element 300 may be less than 200 microns. As an example, the size of the light emitting element 300 may be less than 100 microns, less than 50 microns, or the like.

The light emitting element 300 may include a body potion 310 and an electrode 320. The body potion 310 may include an N-type semiconductor layer 311, a P-type semiconductor layer 312, and an active layer 313 positioned therebetween.

The body portion 310 of the light emitting element 300 may be understood as a portion of the light emitting element 300 other than the electrode 320.

The material of the body portion 310 of the light emitting element 300 may include, but is not limited to compound semiconductor, such as Gallium Nitride (GaN), Aluminum Indium Gallium Phosphide (AlInGaP), or Aluminum Gallium Arsenide (AlGaAs), or Gallium Arsenide Phosphide (GaAsP).

The electrode 320 may include a first electrode 321 and a second electrode 322. The first electrode 321 is electrically connected to the P-type semiconductor layer 312. The second electrode 322 is electrically connected to the N-type semiconductor layer 311. The first electrode 321 may be a positive electrode, and the second electrode 322 may be a negative electrode.

The electrode 320 may include an alloy or solid solution of metals such as gold (Au), tin (Sn), nickel (Ni), titanium (Ti), aluminum (Al), silver (Ag), and indium (In). As an example, electrode 320 includes a gold-indium alloy.

The first electrode 321 and the second electrode 322 may both be positioned on the same side of the body portion 310. As an example, the first electrode 321 and the second electrode 322 are both positioned on a side of the N-type semiconductor layer 311 close to the P-type semiconductor layer 312. In a film layer structure of the display panel, both the first electrode 321 and the second electrode 322 may be positioned on a side of the body portion 310 facing the drive substrate 200. In transferring of the light emitting element 300 to the drive substrate 200, it is convenient to realize electrical connection between the light emitting element 300 and the drive substrate 200 by thermal compression, for example, to realize the bonding between the light emitting element 300 and the drive substrate 200 by means of eutectic.

The body portion 310 may further include an insulation layer 314. The insulation layer 314 covers the N-type semiconductor layer 311, the P-type semiconductor layer 312 and the active layer 313 in the body portion. The insulation layer 314 is provided with through holes to respectively expose a part of region of the N-type semiconductor layer 311 and a part of region of the P-type semiconductor layer 312. At the through hole of the insulation layer 314, the first electrode 321 is electrically connected to the P-type semiconductor layer 312, and the second electrode 322 is electrically connected to the N-type semi conductor layer 311.

The body portion 310 may further include a Bragg reflection layer, which may be positioned on a side of the P-type semiconductor layer 312 away from the N-type semiconductor layer 311. A light extraction efficiency of the light emitting element 300 may be improved by reflection of light.

As shown in FIG. 5, the body portion 310 of the light emitting element 300 may further include a transparent electrode 315. The transparent electrode 315 is positioned between the first electrode 321 and the P-type semiconductor layer 312. The material of the transparent electrode 315 may be indium tin oxide (ITO), which may be configured to adjust the current density distribution in different regions of the light emitting element 300.

As shown in FIG. 5, micro-patterns may be provided on an upper surface of the light emitting element 300. For example, a rough pattern may be provided on an upper surface of the N-type semiconductor layer 311 to facilitate the improvement of the light extraction efficiency of the light emitting element 300.

As shown in FIG. 3, the drive substrate 200 may further include a planarization layer 230. The planarization layer 230 may be positioned on the drive circuit layer 220. The planarization layer 230 may be configured to form a flat surface on the drive circuit layer 220. As an example, the planarization layer 230 may be positioned on the passivation layer 228, and a side of the planarization layer 230 away from the passivation layer 228 having a substantially flat upper surface. The planarization layer 230 may include an organic material such as photoresist, polyacrylate-based resin, polyimide-based resin, polyamide-based resin, siloxane-based resin, acrylic-based resin, epoxy-based resin, or the like.

The drive circuit layer 220 is fabricated by stacking film layers. Patterns such as the active pattern 222, the gate 224, the source 227s and the drain 227d of the drive circuit layer 220, which constitute the thin film transistor TFT, and patterns such as the capacitor C and the wiring L make an upper surface of the drive circuit layer 220 uneven. In addition, the through holes (such as the first contact via CH1 and the second contact via CH2) extending through the film layer bring about the problem of unevenness of the upper surface of the drive circuit layer 220. The upper surface of the drive circuit layer 220 may be an upper surface of the passivation layer 228. By providing the planarization layer 230, a flat surface can be provided for the components to be fabricated subsequently.

With further reference to FIG. 3, the drive substrate 200 may further include a connection portion 240. The connection portion 240 is arranged on the planarization layer 230. The connection portion 240 includes a first connection portion 241 and a second connection portion 242. The first connection portion 241 may be electrically connected to the thin film transistor TFT in the drive circuit layer 220. The second connection portion 242 may be electrically connected to a power line. As an example, the first connection portion 241 may be electrically connected to the drain 227d of the thin film transistor TFT through a contact via CH. The contact via CH penetrates through the planarization layer 230 and the passivation layer 228. The contact via CH exposes a part of the drain 227d of the thin film transistor TFT. The connection portion 240 may include metals such as aluminum (Al), silver (Ag), chromium (Cr), titanium (Ti), tantalum (Ta), molybdenum (Mo); alloys thereof; nitrides thereof; conductive metal oxides; transparent conductive materials; and the like. As an example, the connection portion 240 may include a Ti/Ai/Ti metal stacked structure. The material of the connection portion 240 may be the same as that of the source 227s and the drain 227d.

In order to make full use of the metal film layer, the metal film layer where the connection portion 240 is positioned may further include other metal components, such as power lines, signal lines, electrical shielding components, light shielding components.

As shown in FIG. 3 to FIG. 5, the drive substrate 200 further includes a first film layer 250, and the first film layer 250 is provided with an opening OP.

The first film layer 250 of the drive substrate 200 is positioned on a side of the drive circuit layer 220 away from the substrate 210, that is, the drive circuit layer 220 is positioned between the first film layer 250 and the substrate 210.

The planarization layer 230 may be positioned between the first film layer 250 and the drive circuit layer 220.

The connection portion 240 is positioned between the planarization layer 230 and the first film layer 250.

The opening OP of the first film layer 250 exposes the connection portion 240. The electrode 320 of the light emitting element 300 includes a first portion 320a positioned in the opening OP. The electrode 320 of the light emitting element 300 is in contact with and electrically connected to the connection portion 240. Specifically, the first portion 320a of the electrode 320 of the light emitting element 300 is in contact with and electrically connected to the connection portion 240.

The electrode 320 may fill the opening OP of the first film layer 250. The first portion 320a of the electrode 320 may fill the opening OP of the first film layer 250. Specifically, a lower surface 320b of the electrode 320 is in contact with the connection portion 240. A side 320s of the first portion 320a of the electrode 320 is in contact with a sidewall OPW of the opening OP of the first film layer 250. In this arrangement, the electrode 320 is not only in contact with the connection portion 240 but also in contact with the first film layer 250, which solves the problems of the weak adhesion between the electrode 320 and the metal film layer and the light emitting element being likely to fall off from the drive substrate 200 or being poorly electrically contacted with the drive substrate 200, and improves the reliability of the display panel.

The upper surface of the connection portion 240 may be roughened to increase the adhesion between the connection portion 240 and the first portion 320a of the electrode 320.

The thickness of the first film layer 250 may be adjusted to adjust the contact area between the electrode 320 and the sidewall OPW of the opening OP of the first film layer 250. For example, the thickness of the first film layer 250 is increased to increase the contact area between the electrode 320 and the first film layer 250 and improve the adhesion reliability between the light emitting element 300 and the drive substrate 200.

The inclination of the sidewall OPW of the opening OP of the first film layer 250 may be adjusted to adjust the contact area between the electrode 320 and the sidewall OPW of the opening OP of the first film layer 250. For example, along the direction from the substrate 210 to the light emitting element 300, the sidewall OPW of the opening OP is inclined toward the direction away from the interior of the opening, and the distance from the sidewall OPW to the center of the opening can be increased to increase the contact area between the electrode 320 and the first film layer 250 and improve the adhesion reliability between the light emitting element 300 and the drive substrate 200.

The electrode 320 may further include a second portion 320c positioned between the first portion 320a and the body portion 310 of the light emitting element 300.

FIG. 4 and FIG. 5 illustrate the first portion 320a and the second portion 320c of the first electrode 321. The first portion 320a and the second portion 320c of the second electrode 322 may be divided in the same way. That is, the second electrode 322 includes the first portion 320a positioned at the opening OP of the first film layer 250 and the second portion 320c positioned between the first portion 320a and the body portion 310 of the light emitting element 300.

As shown in FIG. 3 to FIG. 5, the area of the second portion 320c may be greater than or equal to that of the first portion 320a. The edge of the second portion 320c extending beyond the first portion 320a may be in contact with the upper surface of the first film layer 250, which further increases the contact area between the electrode 320 and the first film layer 250 and improves the adhesion reliability between the light emitting element 300 and the drive substrate 200.

The sidewall OPW of the opening OP of the first film layer 250 and the upper surface of the first film layer 250 may be roughened to increase the adhesion between the electrode 320 and the first film layer 250.

In the related art, the electrode of the light emitting element is directly arranged on the metal wired electrode. One end of the metal wired electrode is connected to an underneath thin film transistor through a via of the film layer between the metal wired electrode and the thin film transistor. The electrode of the light emitting element is positioned at the other end of the metal wired electrode. In order to avoid the uneven surface of the metal wired electrode resulted from the position of the via from affecting the bonding process of the light emitting element, a certain distance need to be reserved between the end of the metal wired electrode positioned at the position of the via and the end where the electrode of the light emitting element is arranged, so that the metal wired electrode is long, and the metal wired electrode increases the reflectivity of the display panel and affects the display effect.

In the present application, by arranging the electrode 320 of the light emitting element 300 at the opening OP of the first film layer 250, the metal wired electrode is removed, the reflectivity of the display panel is reduced, and the display effect of the display panel is improved.

In the embodiments of the present invention, the shape of the opening OP of the first film layer 250 being a rectangle is taken as an example. The shape of the opening OP of the first film layer 250 may include other suitable shapes such as a circle.

As shown in FIG. 3, the first electrode 321 of the light emitting element 300 is electrically connected to the first connection portion 241, and is electrically connected to the drain 227d of the thin film transistor TFT through the first connection portion 241. The first connection portion 241 is connected to the thin film transistor TFT through a contact via CH penetrating through the planarization layer 230 and the passivation layer 228. The portion of the first connection portion 241 positioned in the contact via CH generally does not have a flat surface, while the portion of the first connection portion 241 exposed by the opening OP of the first film layer 250 needs to have a relatively flat surface to facilitate the bonding of the light emitting element 300. Along a direction perpendicular to the plane where the display panel 100 is positioned, the contact via CH may not be overlapped with the opening OP of the first film layer 250, so as to avoid the influence of the contact via CH on the flat portion of the first connection portion 241. A distance D between the portion of the first connection portion 241 positioned in the contact via CH and the portion of the first connection portion 241 exposed by the opening OP may be set according to requirements.

With further reference to FIG. 3, the second electrode 322 of the light emitting element 300 is electrically connected to the second connection portion 242, and may be connected to a power line through the second connection portion 242.

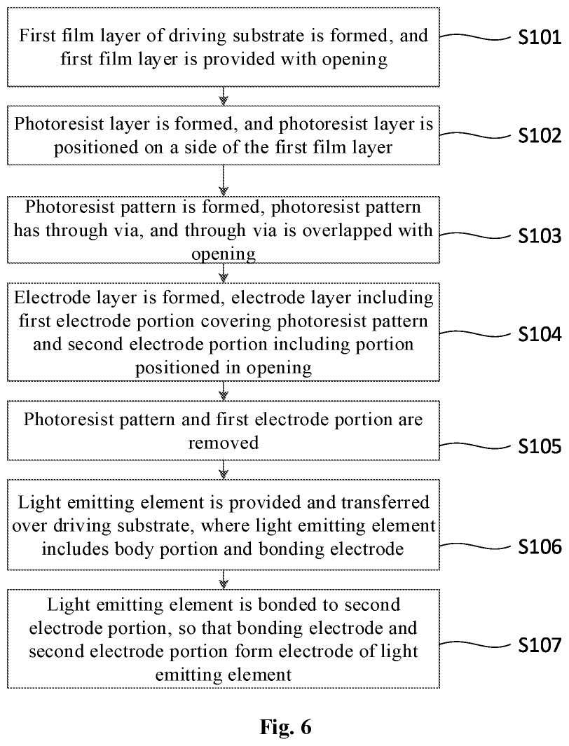

FIG. 6 is a flowchart of a method for forming a display panel according to an embodiment of the present invention.

With reference to FIG. 6 to FIG. 17, the method for forming the display panel according to the embodiments of the present application is described as below.

At S101, a first film layer 250 of a drive substrate 200 is formed, where the first film layer 250 is provided with an opening OP.

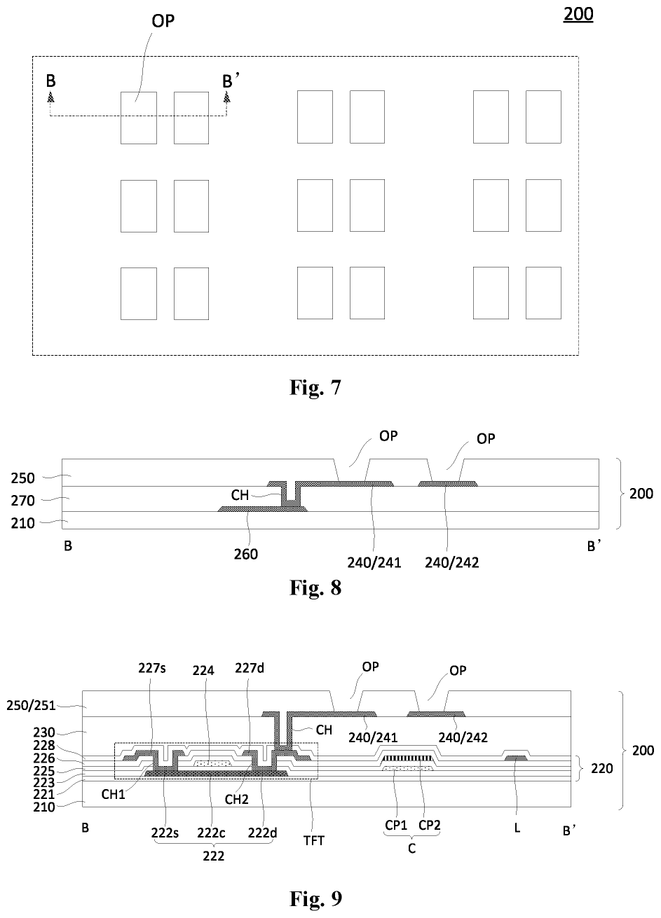

FIG. 7 is a partial top view of a drive substrate according to an embodiment of the present invention. FIG. 8 is a schematic sectional view taken along the line BB′ in FIG. 7. FIG. 9 is another schematic sectional view taken along the line BB′ in FIG. 7. FIG. 8 and FIG. 9 illustrate two examples of the drive substrate respectively, and the subsequent process steps are described by taking the drive substrate of FIG. 9 as an example. It should be noted that the subsequent process steps are also applicable to the drive substrate shown in FIG. 8.

As shown in FIG. 7 and FIG. 8, the drive substrate 200 may include a substrate 210, a wiring layer 260, an insulation layer 270, a connection portion 240 and a first film layer 250.

The wiring layer 260 may be positioned on the substrate 210. The wiring layer 260 may include a plurality of signal lines for transmitting drive signals. In FIG. 8, the drive substrate 200 including one layer of the wiring layer 260 is taken as an example. In other embodiments, the wiring layer 250 may include multiple layers to satisfy the setting requirements of the number and position of the signal lines.

The insulation layer 270 may cover the wiring layer 260.

The connection portion 240 may be arranged on the insulation layer 270, and may be electrically connected to the wiring layer 260 through the contact via CH arranged in the insulation layer 270.

The first film layer 250 is positioned on an upper side of the drive substrate 200. The first film layer 250 is provided with an opening OP. The opening OP exposes the connection portion 240. The opening OP may be configured to receive a portion of the electrode layer formed subsequently.

As shown in FIG. 7 and FIG. 9, the drive substrate 200 may include a substrate 210, a drive circuit layer 220, a planarization layer 230 and a first film layer 250. For the drive substrate 200 in FIG. 9, reference may be made to the drive substrate 200 in FIG. 3 and its related description, and the same parts will not be described in detail again.

The opening OP of the first film layer 250 may be configured to receive a portion of the electrode layer formed subsequently.

It should be noted that, in order to illustrate the structures closely related to each step more clearly, some reference numerals are omitted in the relevant drawings of the subsequent process steps, and reference may be made to other relevant drawings in the present application for the omitted reference numerals.

At S102, a photoresist layer 400 is formed, where the photoresist layer 400 is positioned on a side of the first film layer 250.

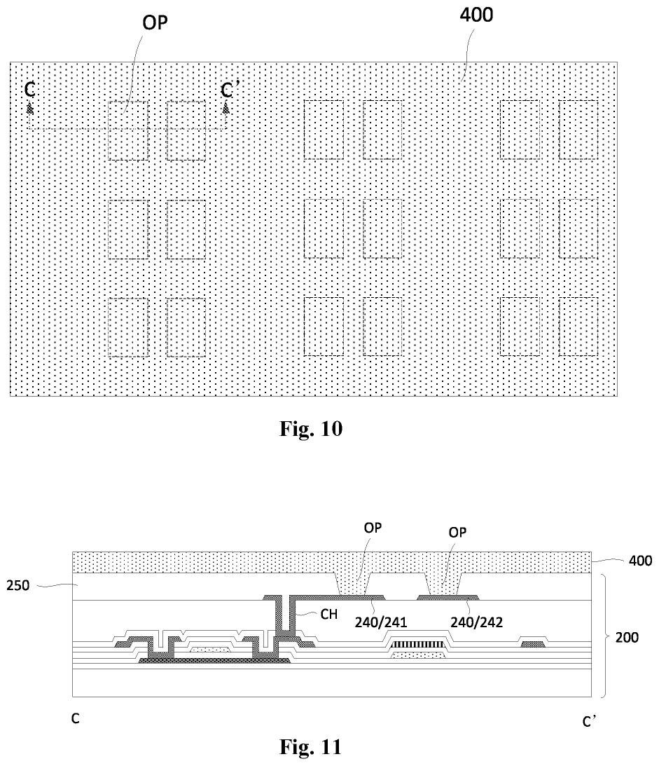

FIG. 10 is a partial top view after forming the photoresist layer on the drive substrate. FIG. 11 is a schematic sectional view taken along the line CC′ in FIG. 10.

As shown in FIG. 10 and FIG. 11, the whole layer of the photoresist layer 400 may be arranged on the upper surface of the drive substrate 200. Specifically, the photoresist layer 400 is arranged on the first film layer 250, and the photoresist layer 400 is in contact with the first film layer 250 and fills the opening OP of the first film layer 250.

At S103, a photoresist pattern 410 is formed, where the photoresist pattern 410 has a through hole 420, and the through hole 420 is overlapped with the opening OP.

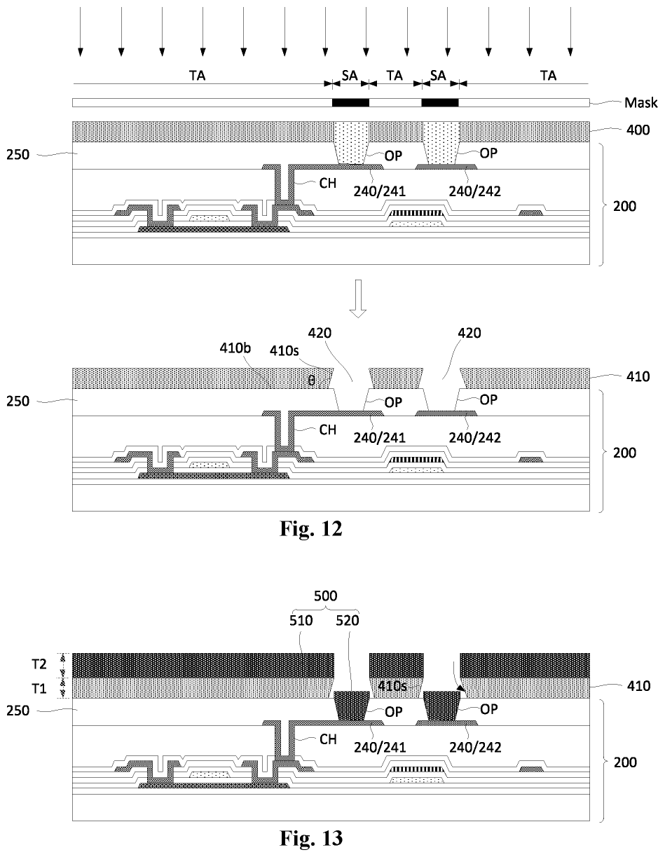

FIG. 12 is a schematic structural view of patterning the photoresist layer.

As shown in FIG. 12, the photoresist layer 400 may be patterned by exposure and development to form the photoresist pattern 410.

Specifically, a mask may be placed over the photoresist layer 400, and light may selectively expose the photoresist layer 400 through the mask, so that the exposed region of to the photoresist layer 400 becomes a soluble substance, or the exposed region of the photoresist layer 400 becomes an insoluble substance. The soluble substance in the photoresist layer 400 is removed by developing to form the photoresist pattern 410.

The material of the photoresist layer 400 may be negative photoresist. The portion of the exposed region of the photoresist layer 400 becomes an insoluble substance and is left in the developing process, while the portion of the non-exposed region of the photoresist layer 400 is removed.

In FIG. 12, the material of the photoresist layer 400 is taken as negative photoresist for illustration. As shown in FIG. 12, the mask MASK includes a light-transmitting area TA and a light-shielding area SA. The light-shielding area SA is directly opposite to the opening OP of the first film layer 250 for shielding the area of the opening OP from light. The area of the photoresist layer 400 that is directly opposite to the light-transmitting area TA of the mask MASK undergoes a photochemical reaction when exposed to light, and becomes an insoluble substance. During the developing process, the portion of the photoresist layer 400 overlapped with the opening is removed to form the photoresist pattern 410.

For the photoresist layer 400 using negative photoresist, during the exposure process, the exposure amounts at different thickness positions are different along the thickness direction of the photoresist layer 400. The further the position away from an exposure source, the less the exposure amount. Positions with insufficient exposure are easily removed in developing, thereby forming the inclined sidewall in the photoresist pattern 410. The photoresist pattern 410 has a through hole 420 overlapped with the opening.

The photoresist pattern 410 includes a bottom surface 410b facing the first film layer 250 and a sidewall 410s positioned in the through hole 420. The included angle θ between the bottom surface 410b of the photoresist pattern 410 and the sidewall 410s is an obtuse angle.

As shown in FIG. 12, the light-shielding area SA of the mask MASK may have the same size as the region where the opening OP is positioned. In other embodiments, the light-shielding area SA of the mask MSAK may be larger than the region where the opening OP is positioned, and the light-shielding area SA is overlapped with the opening OP.

At S104, an electrode layer 500 is formed. The electrode layer 500 includes a first electrode portion 510 covering the photoresist pattern 410 and a second electrode portion 520 including a portion positioned in the opening OP.

FIG. 13 is a schematic structural view after forming the electrode layer. As shown in FIG. 13, an electrode layer 500 may be formed on the photoresist pattern 410 by means of to evaporation or physical vapor deposition. The electrode layer 500 includes the first electrode portion 510 and the second electrode portion 520. The first electrode portion 510 covers the photoresist pattern 410 (i.e., the portion of the photoresist layer 400 that remains during development), and the second electrode portion 520 includes the portion positioned within the opening OP of the first film layer 250.

Since the photoresist pattern 410 has the through hole 420, and the through hole 420 is overlapped with the opening OP of the first film layer 250, when the electrode layer 500 is formed by means of evaporation or physical vapor deposition, the electrode layer 500 not only includes the portion positioned on the photoresist pattern 410, but also includes the portion positioned in the opening OP of the first film layer 250. In addition, by using negative photoresist for the photoresist layer 400, the sidewall 410s inclined toward the center of the through hole 420 can be formed at the through hole 420 of the photoresist pattern 410, so that the second electrode portion 520 and the first electrode portion 510 of the electrode layer 500 are easily disconnected at the through hole 420.

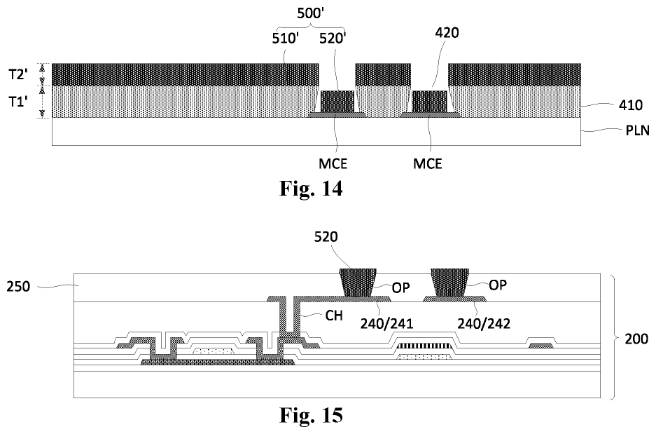

FIG. 14 is a comparison view of FIG. 13.

As shown in FIG. 14, the metal wired electrode MCE is positioned on the flat layer PLN. The photoresist pattern 410 is positioned on the flat layer PLN. The through hole 420 of the photoresist pattern 410 exposes at least a part of region of the metal wired electrode MCE. The electrode layer 500′ includes a first electrode portion 510′ positioned on the upper surface of the photoresist pattern 410 and a second electrode portion 520′ positioned in the through hole 420. In order to ensure that the first electrode portion 510′ and the second electrode portion 520′ are disconnected at the through hole 420, it is necessary to set the thickness T1′ of the photoresist pattern to be greater than the thickness of the electrode layer 500′. Since the second electrode portion 520′ needs to be melted and pressed together with the bonding electrode on the light emitting element 300 during the subsequent bonding of the light emitting element 300 to the drive substrate 200, there is some requirement on the thickness of the second electrode portion 520′. The thickness of the second electrode portion 520′ cannot be too small, and therefore, the thickness T1′ of the photoresist pattern cannot be too small, which results in certain requirements on the process and equipment for forming the photoresist layer and the process and equipment for patterning the photoresist layer, which increases the process difficulty.

In the present application, as shown in FIG. 13, the thickness of the electrode layer 500 is T2, the thickness of the second electrode portion 520 of the electrode layer 500 is also substantially T2, and the second electrode portion 520 further includes the portion within the opening OP of the first film layer 250. In this solution, the first film layer 250 carries a part of the thickness of the electrode layer 500, which reduces the requirement on the thickness T1 of the photoresist layer 400. Specifically, the depth of the opening OP of the first film layer 250 offsets a part of the thickness of the second electrode portion 520, so that the thickness of the part of the second electrode portion 520 positioned in the through hole 420 is less than the thickness T2 of the electrode layer 500, thereby reducing the requirement on the depth of the through hole 420 of the photoresist pattern 410, that is, the requirement on the thickness T1 of the photoresist pattern 420 is reduced, so that the thickness of the photoresist layer can be reduced, the process difficulty of forming photoresist is reduced, and it is compatible with the process equipment for forming other film layers in the display panel.

The electrode layer 500 may include a single metal layer, such as gold (Au), tin (Sn), nickel (Ni), titanium (Ti), aluminum (Al), silver (Ag), and indium (In), or a stacked structure of multiple metal layers. As an example, the electrode layer 500 is a gold (Au) film layer.

In FIG. 12 and FIG. 13, the light-shielding area SA of the mask and the opening OP of the first film layer 250 are taken as having the same size for illustration. In another implementation, the area of the light-shielding area SA may be greater than the area of the opening OP of the first film layer 250, so that the area of the through hole 420 of the formed photoresist pattern 410 may be greater than the area of the opening OP of the first film layer 250. Then the second electrode portion 520 of the electrode layer 500 formed subsequently not only includes the portion filling the opening OP, but also the portion covering the upper surface of the first film layer 250. In bonding of the bonding electrode 330 of the light emitting element 300 to the second electrode portion 520, the contact area between the bonding electrode 330 and the second electrode portion 520 can be increased, and the alignment precision and the bonding reliability can be improved.

At S105, the photoresist pattern 410 and the first electrode portion 510 are removed.

FIG. 15 is a schematic structural view after removing the photoresist pattern.

As shown in FIG. 15, the second electrode portion 520 includes the portion positioned in the opening OP of the first film layer 250. The thickness of the second electrode portion 520 may be greater than the depth of the opening OP. That is, the second electrode portion 520 may further include a portion protruding from the upper surface of the first film layer 250.

After removing the photoresist pattern 410 and the first electrode portion 510 on the photoresist pattern 410 in the structure shown in FIG. 13, the structure shown in FIG. 15 can be obtained.

The photoresist pattern 410 and the first electrode portion 510 may be removed using a stripping solution. The sidewall 410s of the photoresist pattern 410 is inclined, so that there is a gap between the sidewall 410s and the second electrode portion 520, which facilitates the inflow of the stripping solution (as shown by the arrows between the sidewall 410s and the second electrode portion 520 in FIG. 13), thereby smoothly removing the photoresist pattern 410 and the first electrode portion 510 thereon.

At S106, the light emitting element 300a is provided and transferred over the drive substrate 200, where the light emitting element 300a includes a body portion 310 and a bonding electrode 330.

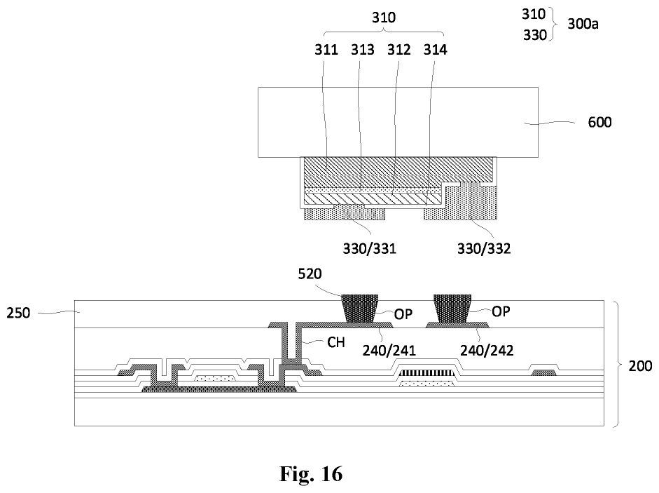

FIG. 16 is a schematic view of transferring the light emitting element.

As shown in FIG. 16, a transfer apparatus 600 transfers the light emitting element 300a over the drive substrate 200. The light emitting element 300a may be additionally formed by processes such as epitaxial growth on a source substrate and patterning, and placed over the drive substrate 200 by means of transfer.

The light emitting element 300a includes the body portion 310 and the bonding electrode 330. The structure of the body portion 310 may refer to FIG. 4 and FIG. 5 and the related description. In addition, reference can be made to FIG. 16, and the same parts will not be described in detail again.

The bonding electrode 330 may include a first bonding electrode 331 and a second bonding electrode 332. The first bonding electrode 331 is electrically connected to the P-type semiconductor layer 312, and the second bonding electrode 332 is electrically connected to the N-type semiconductor layer 311.

The bonding electrode 330 may include a single metal layer such as gold (Au) and indium (In), or a stacked structure of multi metal layers. As an example, the bonding electrode 330 includes an indium (In) film layer.

The transfer apparatus 600 may include a transfer head, a transfer substrate, etc. As an example, the transfer apparatus 600 may be a stamp. The stamp picks up a plurality of light emitting elements 300a through van der Waals force, and releases the light emitting elements 300 at specific positions to complete the transfer of the light emitting elements 300a.

At S107, the light emitting element 300a is bonded to the second electrode portion 520, so that the bonding electrode 330 and the second electrode portion 520 form the electrode 320 of the light emitting element 300.

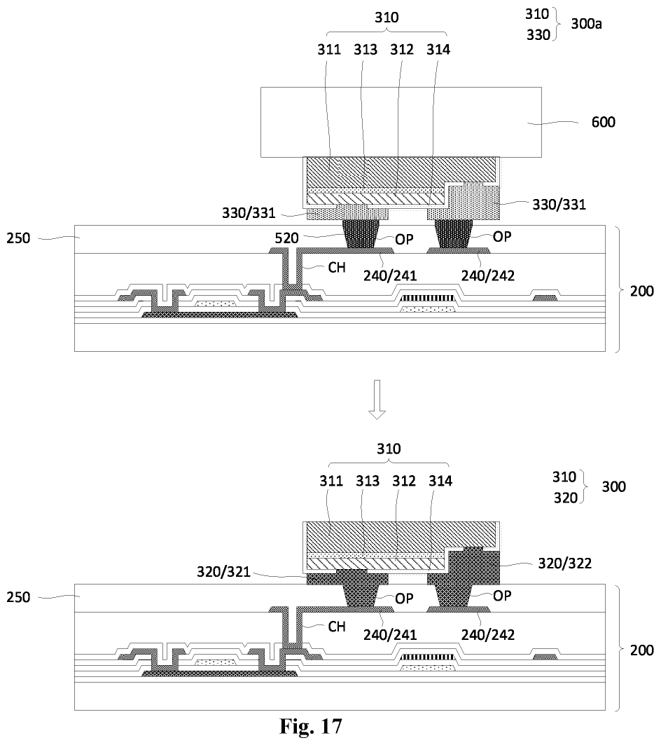

FIG. 17 is a schematic structural view of a process of bonding a light emitting element to a drive substrate.

As shown in FIG. 17, the bonding electrode 330 of the light emitting element 300a is in contact with the second electrode portion 520 on the drive substrate 200, and a eutectic reaction occurs at a certain temperature, so that the bonding electrode 330 and the second electrode portion 520 are crystallized into crystal mixture (eutectic), that is, the electrode 320 (the first electrode 321 and the second electrode 322) of the light emitting element 300 in FIG. 17 are formed. As an example, the second electrode portion 520 includes gold (Au), the bonding electrode 330 includes indium (In), and the electrode 320 of the light emitting element 300 formed by the eutectic reaction between the second electrode portion 520 and the bonding electrode 330 is gold-indium alloy.

During the bonding process, the second electrode portion 520 is melted and pressed, and it is easy to flow. By arranging the second electrode portion 520 in the opening OP, the flow range of the second electrode portion 520 to the surroundings is reduced, and a short circuit caused by contact of the formed first electrode 321 with the second electrode 322 is avoided.

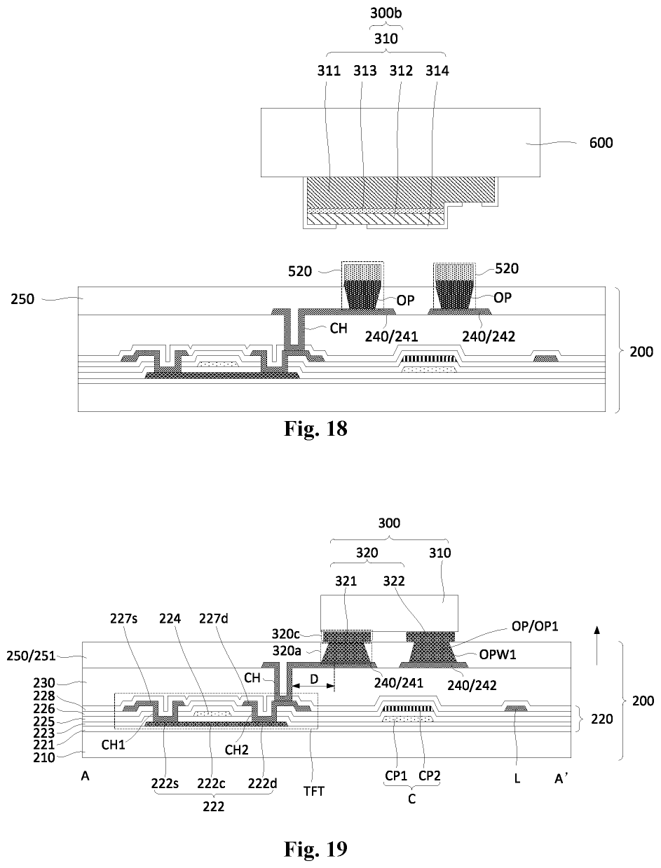

FIG. 18 is another schematic view of transferring a light emitting element.

Another implementation of the method for forming the display panel according to the embodiments of the present invention will be described with reference to FIG. 6 and FIG. 18.

Steps S101-S103 and S105 can be the same as described above, and the processes of S104, S106 and step S107 are described below.

At S104, an electrode layer 500 is formed. The electrode layer 500 includes a first electrode portion 510 and a second electrode portion 520. The first electrode portion 510 covers the photoresist pattern 410, and the second electrode portion 520 includes the portion positioned in the opening OP.

In this step, the electrode layer 500 includes a first metal and a second metal that are stacked. For example, the first metal is gold (Au), and the second metal is indium (In).

At S106, the light emitting element 300b is provided and transferred over the drive substrate 200, where the light emitting element 300b includes the body portion 310.

At S107, the light emitting element 300b is bonded to the second electrode portion 520, so that the second electrode portion 520 forms the electrode 320 of the light emitting element 300.

In this step, the first metal and the second metal stacked in the second electrode portion 520 undergo eutectic reaction to form a gold-indium alloy, which serves as the electrode 320 of the light emitting element 300. At the same time, during the bonding process, the body portion 310 of the light emitting element 300b also contacts with the second electrode portion 520 and forms a fixed electrical connection.

As shown in FIG. 3, the first film layer 250 may include a first organic layer 251 including photoresist, polyacrylate-based resin, polyimide-based resin, polyamide-based resin, siloxane-base resins, acrylic-based resins, epoxy-based resins, or the like.

Based on step S104 in FIG. 6, FIG. 13 to FIG. 14 and related text descriptions, setting the first film layer 250 to include the first organic layer 251 can provide an opening OP with a certain depth and reduce the requirements on thickness of the photoresist layer 400, thereby reducing the process difficulty. At the same time, the first organic layer 251 can continue to provide a flat surface over the connection portion 240, which facilitates the smooth eutectic process between the second electrode portion 520 and the bonding electrode 330, and improves the reliability in electrode bonding. Based on this, the first organic layer 251 may serve as the second planarization layer.

FIG. 19 is another schematic sectional view taken along the line AA′ in FIG. 2.

As shown in FIG. 19, the first organic layer 251 is provided with a first opening OP1, and the opening OP of the first film layer 250 includes the first opening OP1. Along the direction from the first film layer 250 to the light emitting element 300 (as shown by the arrow in the drawing), the sidewall OPW1 of the first opening OP1 is inclined toward the interior of the first opening OP1, that is, the area of the top surface (close to the body portion 310 of the light emitting element 300) of the first opening OP1 is less than the area of the bottom surface (close to the connection portion 240) of the first opening OP1.

The electrode 320 of the light emitting element 300 includes the first portion 320a filling the first opening OP1, and in conjunction with the inclined arrangement of the sidewall OPW1 of the first opening OP1, the ability of the drive substrate 200 to fix the light emitting element 300 is improved, and probability for the light emitting element 300 to fall off from the drive substrate 200 is reduced.

For the parts in FIG. 19 that have the same reference numerals as those in FIG. 3, reference may be made to the foregoing content, which will not be repeated here.

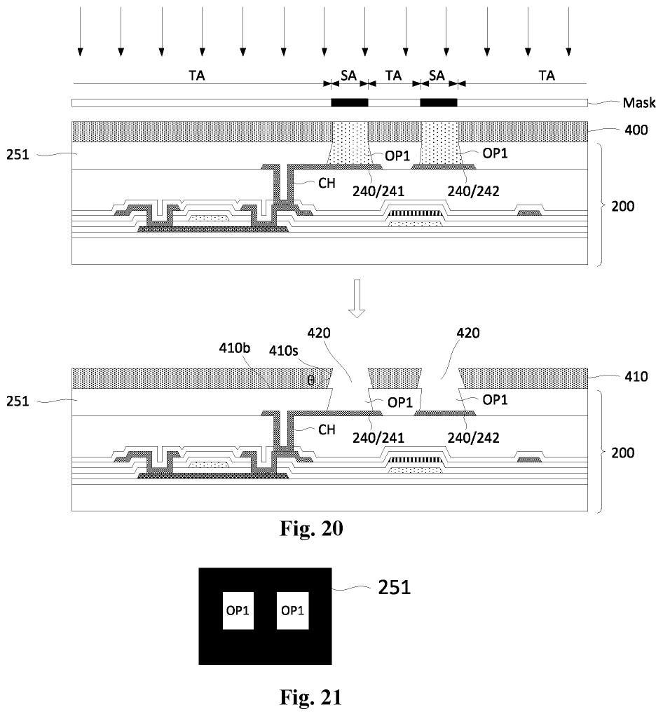

FIG. 20 is another schematic structural view of patterning the photoresist layer.

Based on the structure of the first organic layer 251 in FIG. 19, the process of step S103 in FIG. 6 is illustrated in FIG. 20.

In the method for forming the display panel, at step S101, forming the first film layer 250 of the drive substrate 200 includes the steps as described below.

The first organic layer 251 is formed, and the first organic layer 251 is provided with the first opening OP1.

The structure of the first organic layer 251 may refer to FIG. 3, FIG. 19 and FIG. 20.

The first organic layer 251 may include negative photoresist.

The structure formed by the first organic layer 251 using negative photoresist can be referred to FIG. 19 and FIG. 20.

As shown in FIG. 19, the first organic layer uses negative photoresist, so that the sidewall OPW1 of the formed first opening OP1 is inclined toward the interior of the first opening OP1.

As shown in FIG. 20, in the case where both the first organic layer 251 and the photoresist layer 400 use negative photoresist, the mask MASK having the same light-shielding area pattern (for example, a same mask) can be used to form the first organic layer 251 and the photoresist pattern 410, so as to save the cost of forming the mask.

The first organic layer 251 includes a light absorbing material. The first organic layer 251 can be configured to shield light, and plays a role in reducing the reflectivity of the display panel by absorbing external ambient light. For example, the first organic layer 251 includes a black pigment. As an example, the first organic layer 251 may be black photoresist.

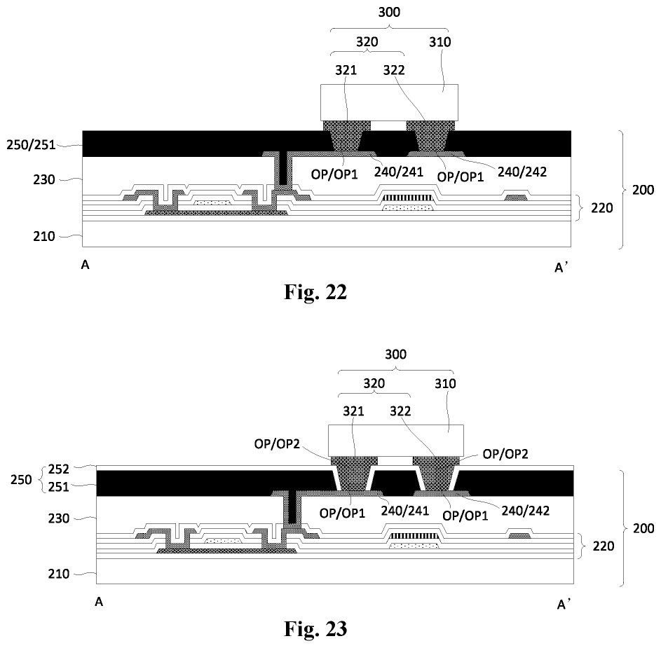

FIG. 21 is a partial top view of a first organic layer. FIG. 22 is another schematic sectional view taken along the line AA′ in FIG. 2. The difference between FIG. 22 and FIG. 3 is that the first organic layer 251 in FIG. 3 can transmit light, while the first organic layer 252 in FIG. 22 includes a light absorbing material. For other structures in FIG. 22, reference can be made to FIG. 3 and its related text description, which will not be repeated here.

As shown in FIG. 21 and FIG. 22, except for the position where the first opening OP1 is provided, other parts of the first organic layer 251 can block light. First, the first organic layer 251 can greatly reduce the problem of high reflectivity of the display panel caused by the metal assemblies in the drive circuit layer 220. Second, the first organic layer can also reduce the influence of external ambient light on the performance of the elements in the drive circuit layer 220, for example, the problem of light leakage from the thin film transistor caused by the external ambient light entering the thin film transistor is avoided. Third, the first organic layer 251 can absorb the light emitted downward from the light emitting element 300 to prevent the light from being reflected and affecting the display effect.

In the implementations where the first organic layer 251 is negative photoresist, the first organic layer 251 may include a light absorbing material. As an example, the first organic layer 251 in FIG. 19 may transmit light, or the first organic layer 251 in FIG. 19 may include a light absorbing material to block light.

The first film layer 250 of the display panel may further include a protective layer 252.

FIG. 23 is another sectional schematic view taken along the line AA′ in FIG. 2. The difference between FIG. 23 and FIG. 22 is that the first film layer 250 in FIG. 22 includes the first organic layer 251, while the first film layer 250 in FIG. 23 includes the first organic layer 251 and the protective layer that are stacked. Other structures in FIG. 23 may be referred to FIG. 3, FIG. 22 and its related text descriptions, which will not be repeated here.

As shown in FIG. 23, the first film layer 250 in the display panel includes a first organic layer 251 and a protective layer 252 covering the first organic layer 251 and in contact with the first organic layer 251.

The first organic layer 251 is provided with the first opening OP1. The protective layer 252 is provided with a second opening OP2. The first opening OP1 is overlapped with the second opening OP2. The opening OP of the first film layer 252 may be constituted by the first opening OP1 and the second opening OP2.

The electrode 320 includes portions arranged within the first opening OP1 and the second opening OP2.

The protective layer 252 may cover the upper surface of the first organic layer 251 and the sidewall of the first opening OP of the first organic layer 251, that is, the protective layer 252 wraps the exposed surface of the first organic layer.

The portion of the electrode 320 of the light emitting element 300 positioned in the opening OP is in contact with the protective layer 252.

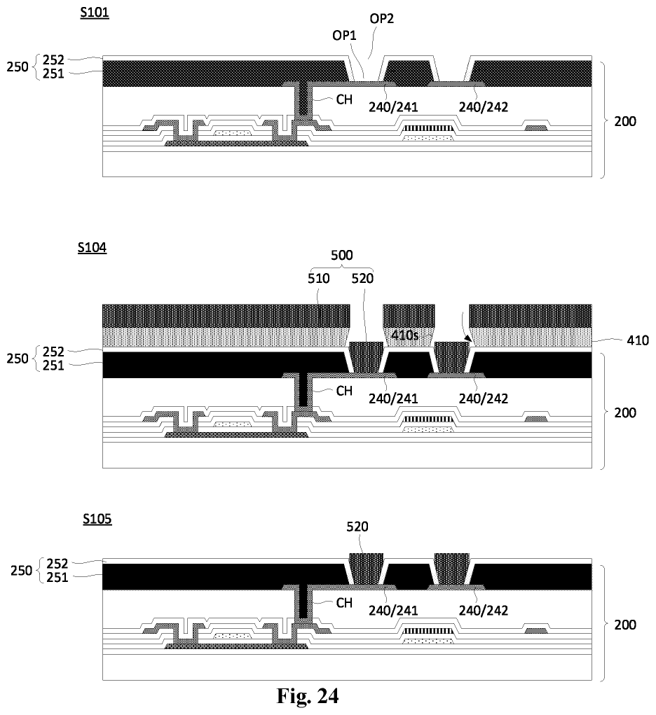

For the implementation in which the first film layer 250 includes the first organic layer 251 and the protective layer 252 that are stacked, the process of steps S101, S104 and S105 in FIG. 6 is illustrated in FIG. 24.

FIG. 24 is a schematic structural view of the process of forming a first film layer, forming an electrode layer and removing a part of the electrode.

With reference to FIG. 6 and FIG. 24, the steps S101, S102, S104 and S105 in the method for forming the display panel are described below.

At Step S101, forming the first film layer 250 of the drive substrate 200 includes:
forming the first organic layer 251, the first organic layer 251 being provided with the first opening OP1;
forming the protective layer 252, the protective layer 252 covering the first organic layer 251, and the protective layer 252 being provided with the second opening OP2 overlapped with the first opening OP1.

At Step S102, forming the photoresist layer 400 positioned on a side of the first film layer 250 includes:
the photoresist layer 400 being positioned on the side of the protective layer 252 away from the first organic layer 251.

At Step S104, the electrode layer 500 is formed. The electrode layer 500 includes the first electrode portion 510 and the second electrode portion 520. The first electrode portion 510 covers the photoresist pattern 410. The second electrode portion 520 includes a portion positioned in the opening OP.

At Step S105, the photoresist pattern 410 and the first electrode portion 510 are removed.

The photoresist pattern 410 and the first electrode portion 510 are removed using the stripping solution. During the process of forming the structure in step S105 from the structure in step S104, the stripping solution flows into the gap between the sidewall 410s of the photoresist pattern 410 and the second electrode portion 520, as shown by arrows in the structural view of step S104 in FIG. 24.

In the structure without the protective layer 252 (as shown in FIG. 22), the first organic layer 251 is exposed at the gap, and the stripping solution contacts the first organic layer 251 at the gap, causing black photoresist that makes up the first organic layer to fade and fail.

The protective layer 252 is provided. The protective layer 252 covers the exposed surface of the first organic layer 251 to isolate the first organic layer 251 from the stripping solution, which can prevent the first organic layer 251 from contacting and being corroded by the stripping solution in the removing of the photoresist pattern 410, thereby preventing the first organic layer 251 from being fading and failing.

The protective layer 252 can be made of a material resistant to the influence of the stripping solution.

The protective layer 252 may include an inorganic layer. The portion of the electrode 320 positioned in the opening OP is in contact with the inorganic layer 252, and the electrode 320 and the inorganic layer 252 have good adhesion, which can prevent the electrode 320 from falling off. The protective layer 252 may include a stacked structure composed of one or more of the inorganic materials such as silicon oxide, silicon nitride, and silicon oxynitride.

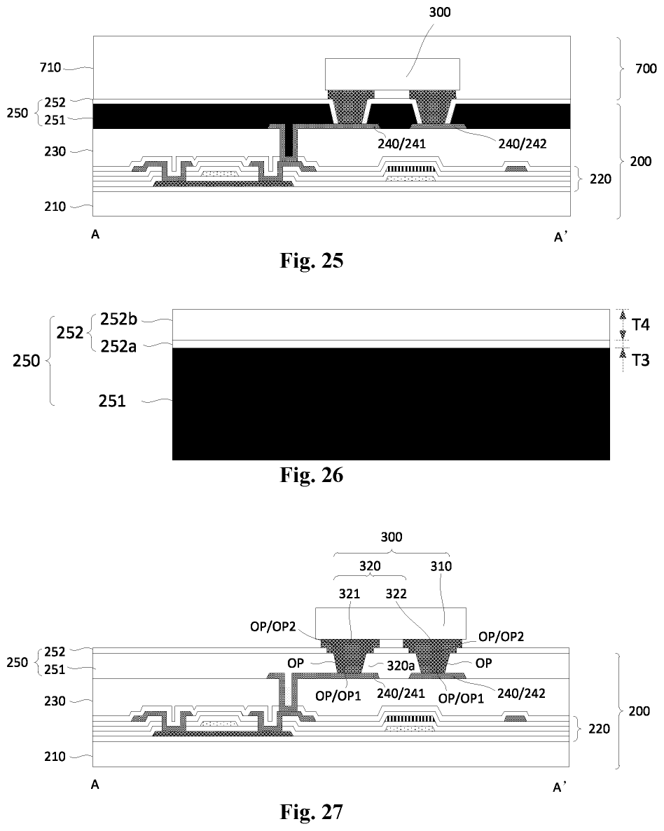

FIG. 25 is another schematic sectional view taken along the line AA′ in FIG. 2.

As shown in FIG. 25, the display panel further includes a package layer 700. The package layer 700 is configured to package the light emitting element 300. The package layer 700 may include a package gule 710, and the package gule 710 may cover the drive substrate 200 and the light emitting element 300.

In the implementation in which the first organic layer 251 in the first film layer 250 includes a light absorbing material, the first organic layer 251 is configured to reduce the reflectivity of the display panel. After the protective layer 252 is added in the first film layer 250, an interface between the protective layer 252 and the package gule 710 is newly added in the display panel, and the newly added interface is likely to bring about the problem of increased reflectivity, which hinders the realization of the purpose of reducing the reflectivity of the display panel by using the first organic layer 251.

Based on this, the protective layer 252 may include a silicon oxide layer.

The refractive index of the silicon oxide layer approximates the refractive index of the material of the package layer 700. For example, the refractive index of the silicon oxide layer approximates the refractive index of the package gule 710, which reduces the interface reflection between the protective layer 252 and the package gule 710. The problem of increased reflectivity caused by a large difference in refractive index is improved.

FIG. 26 is a schematic structural view of a first film layer according to an embodiment of the present invention.

As shown in FIG. 26, the first film layer 250 includes a first organic layer 251 and a protective layer 252. The protective layer 252 includes a silicon nitride layer 252a and a silicon oxide layer 252b that are stacked, and the silicon nitride layer 252a is positioned between the silicon oxide layer 252b and the first organic layers 251.

A silicon oxide layer is directly deposited on the first organic layer 251, and the silicon oxide layer is prone to crack and fall off. A silicon nitride layer 252a is added between the silicon oxide layer 252b and the first organic layer 251. The silicon nitride layer 252a can play a transition role between the silicon oxide layer 252b and the first organic layer 251, which improves the film bonding performance between the protective layer 252 and the first organic layer 251 to prevent film layer separation.

As shown in FIG. 26, the thickness T3 of the silicon nitride layer 252a is less than the thickness T4 of the silicon oxide layer 252b. Specifically, T3≤40 nm, 200 nm≤T4≤400 nm. As an example, T3=30 nm, T4=200 nm, or, T3=30 nm, T4=400 nm. By setting the thickness T3 of the silicon nitride layer 252a to be less than the thickness T4 of the silicon oxide layer 252b, the reflectivity problem caused by the interface between the silicon nitride layer 252a and the silicon oxide layer 252b can be alleviated.

FIG. 27 is another sectional schematic view taken along the line AA′ in FIG. 2.

As shown in FIG. 27, the first film layer 250 includes a first organic layer 251 and a protective layer 252. The first organic layer 251 is provided with a first opening OP1, and the protective layer 252 is provided with a second opening OP2, where the second opening OP2 is larger than the first opening OP1.

In bonding of the bonding electrode 330 of the light emitting element 300a to the second electrode portion 520, the bonding electrode 330 and the second electrode portion 520 are melted and pressed, which is likely to cause the melted part to flow and diffuse to the surroundings. By providing the protective layer 252 and providing the second opening OP2 of the protective layer 252 as being greater than the first opening OP1 of the first organic layer 251, more space can be provided to accommodate the melted part of the second electrode portion 520 and the bonding electrode 330 to prevent short circuit between the formed electrodes 320. In addition, after the bonding electrode 330 and the second electrode portion 520 form an eutectic (such as the electrode 320), the eutectic contacts both the sidewall of the first organic layer 251 and the protective layer 252, thereby improving the adhesive force between the electrode 320 and the first film layer 250 and preventing the light emitting element 300 from falling off.

In FIG. 27, the first organic layer 251 in the first film layer 250 being a light-transmitting film layer is taken as an example. In another implementation, the first organic layer 251 in FIG. 27 can be replaced with a film layer containing a light absorbing material, and the film layer containing a light absorbing material can refer to the first organic layer 251 in FIG. 22, FIG. 23 and FIG. 25. In yet another implementation, the first organic layer 251 in FIG. 27 may be replaced with a film layer containing negative photoresist, and the film layer containing negative photoresist can refer to the first organic layer 251 in FIG. 19.

Regarding the size relationship between the first opening OP1 of the first organic layer 251 and the second opening OP2 of the protective layer 252, the second opening OP2 may be set to be smaller than the first opening OP1, which can alleviate the problem that the light emitting element 300 is likely to fall off.

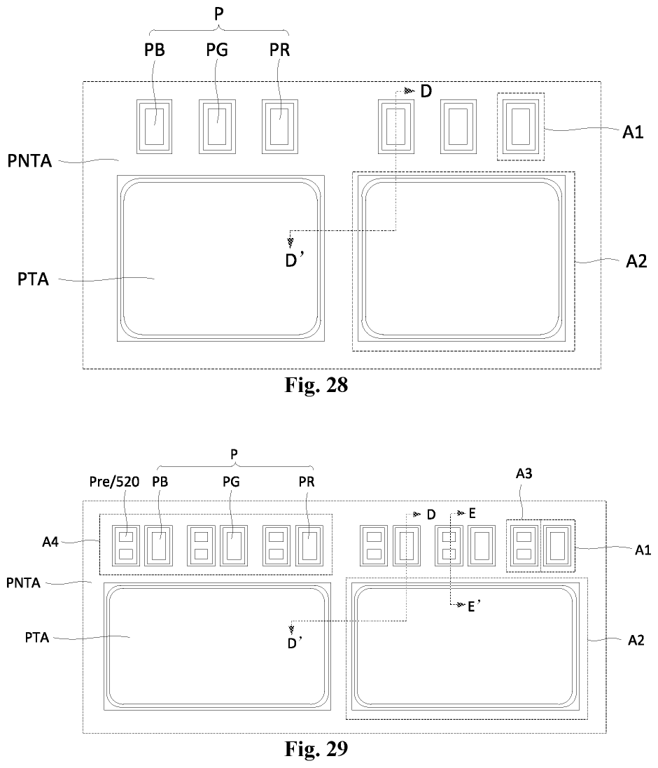

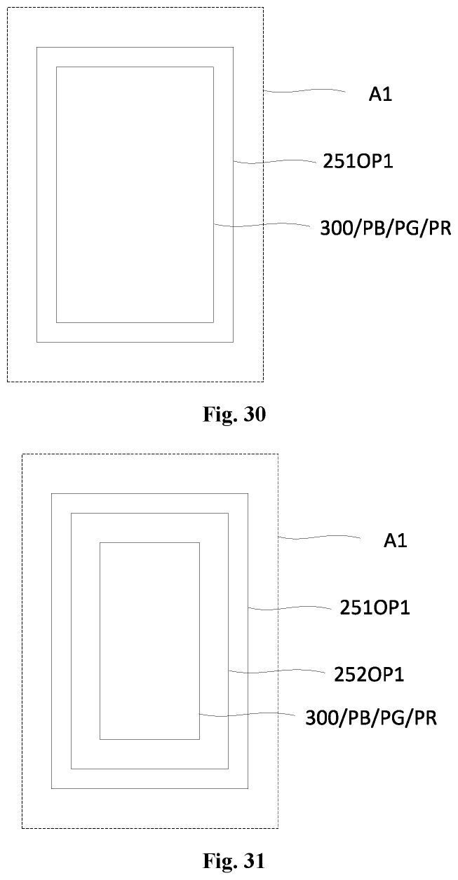

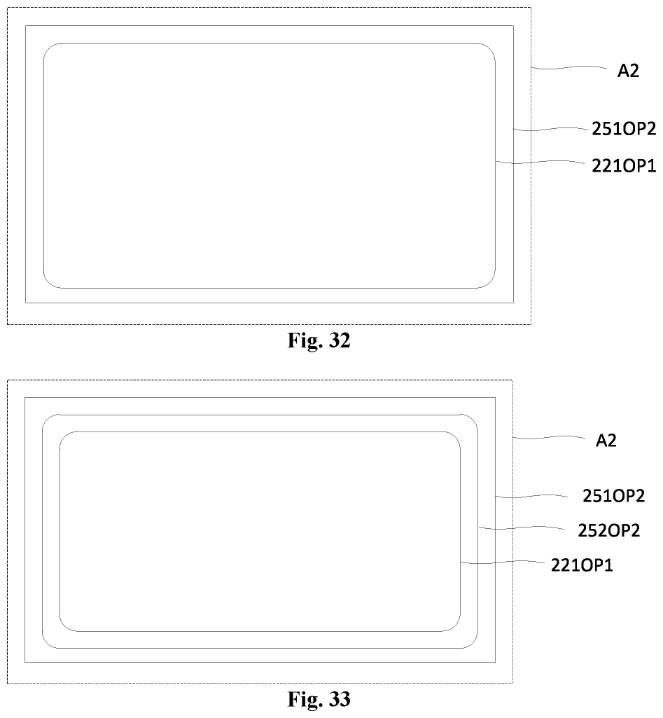

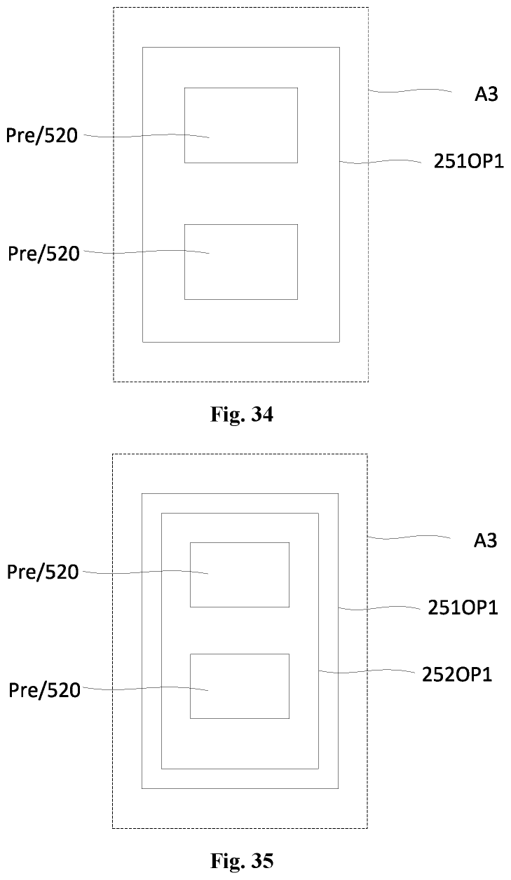

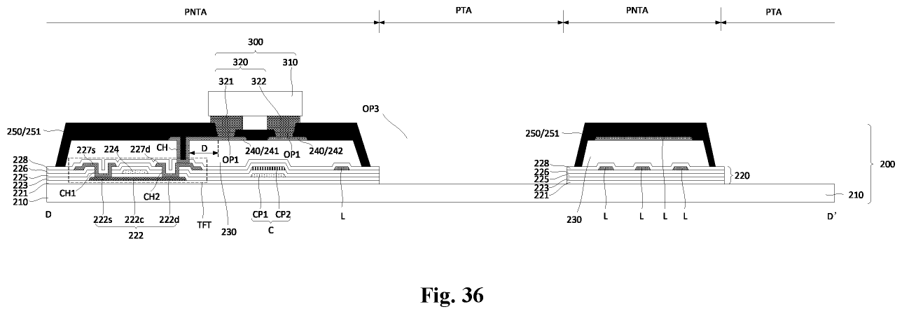

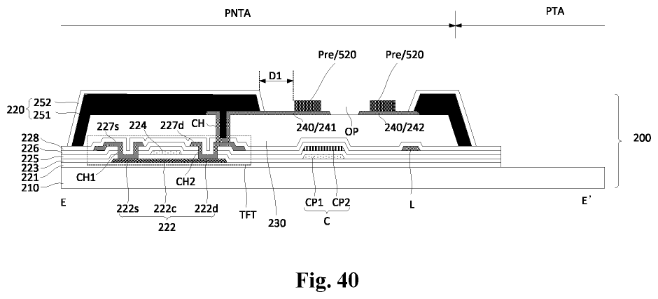

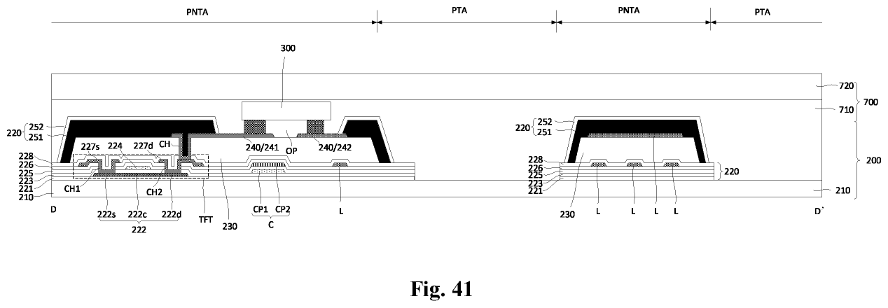

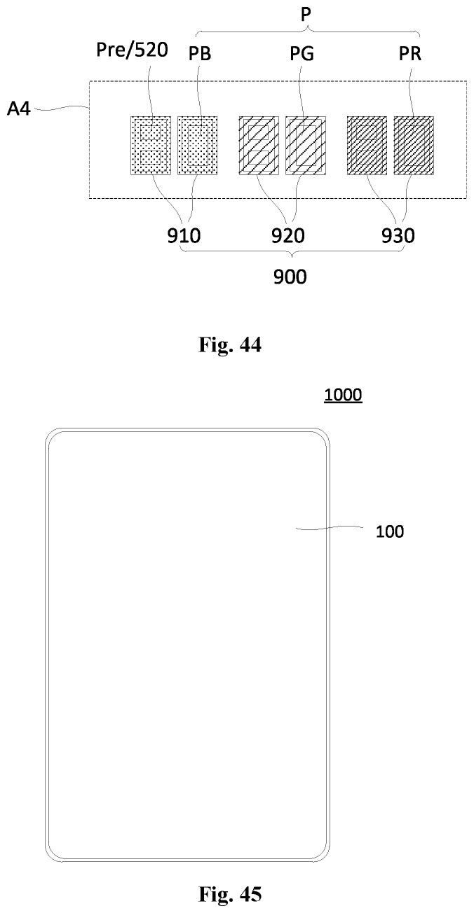

FIG. 28 and FIG. 29 are each another schematic enlarged view of a part of the display area in FIG. 1. FIG. 30 and FIG. 31 are each a schematic enlarged view of a region A1 in FIG. 28 and FIG. 29. FIG. 32 and FIG. 33 are each a schematic enlarged view of a region A2 in FIG. 28 and FIG. 29. FIG. 34 and FIG. 35 are each a schematic enlarged view of a region A3 in FIG. 28 and FIG. 29. FIG. 36 to FIG. 39 are each a schematic sectional view taken along the line DD′ in FIG. 28 and FIG. 29. FIG. 40 is a schematic sectional view taken along the line EE′ in FIG. 29. FIG. 41 to FIG. 43 are schematic sectional views taken along the line DD′ in FIG. 28 and FIG. 29 respectively. FIG. 44 is a schematic enlarged view of a region A4 in FIG. 29.

It should be noted that, FIG. 30 to FIG. 35 illustrate the shapes of the openings of the relevant film layers and the size relationship of each opening respectively. The opening marks of the first organic layer 251 are taken as an example, which are marked as 251OP1 and 251OP2 in FIG. 30 to FIG. 35, respectively.

FIG. 30, FIG. 32 and FIG. 34 illustrate implementations in which the first film layer 250 includes the first organic layer 251.

FIG. 31, FIG. 33 and FIG. 35 illustrate implementations in which the first film layer 250 includes a first organic layer 251 and a protective layer 252.

For the parts in FIG. 28 to FIG. 43 that are the same as those in the preceding figures, reference may be made to the foregoing content, which will not be repeated here.

As shown in FIG. 28 to FIG. 44, the display panel includes a pixel light-transmitting area PTA and a non-light-transmitting area PNTA. The non-light-transmitting area PNTA includes a light emitting element setting area.

The light emitting element setting area is the region where the light emitting element 300 is bonded. As shown in FIG. 28, the light emitting element setting area includes regions for setting a blue light emitting element PB, a green light emitting element PG, and a red light emitting element PR, respectively. As shown in FIG. 29, the light emitting element to setting area includes regions for setting the blue light emitting element PB, the green light emitting element PG, and the red light emitting element PR, respectively, and includes a redundant setting area Pre. When the bonded light emitting element 300 fails, the normal light emitting element 300 can be re-bonded in the redundant setting area Pre for repair. The two connection portions 240 in the redundant setting area Pre may be respectively connected to the two connection portions 240 in the adjacent light emitting element setting area.

The blue light emitting element PB, the green light emitting element PG, and the red light emitting element PR may be configured to constitute the pixel P.

The first organic layer 251 in the first film layer 250 includes a light absorbing material and transmits light through the openings. The first organic layer 251 is provided with a first opening OP1 (or an opening OP) and a third opening OP3. The first opening OP1 defines a light emitting element setting area, and the third opening OP3 defines a pixel light-transmitting area PTA.

As shown in FIG. 36, the first film layer 250 includes a first organic layer 251, and the electrode 320 of the light emitting element 300 fills the first opening OP1 of the first organic layer 251.

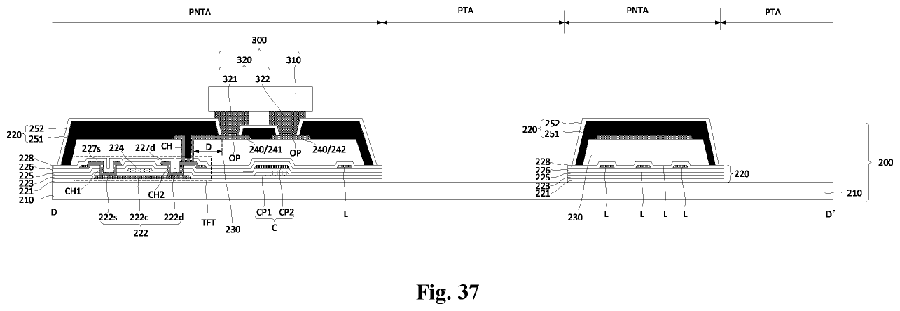

As shown in FIG. 37, the first film layer 250 includes a first organic layer 251 and a protective layer 252. The first organic layer 251 and the protective layer 252 together form an opening OP of the first film layer 250, and the electrode 320 of the light emitting element 300 fills the opening OP and in contact with the protective layer 252.

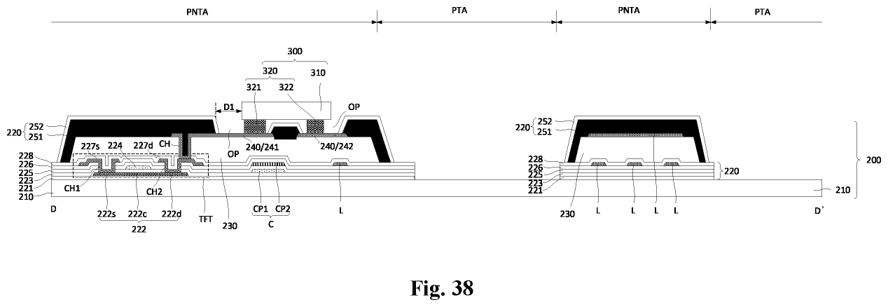

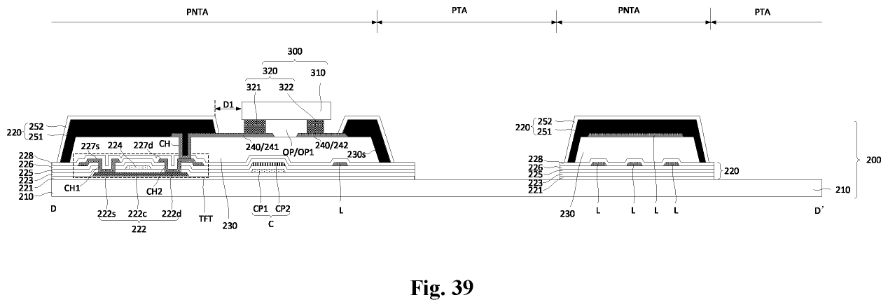

As shown in FIG. 38 and FIG. 39, the first film layer 250 includes a first organic layer 251 and a protective layer 252. In a first direction, the distance D1 between the light emitting element 300 and the edge of the first opening OP1 is greater than zero, where the first direction is parallel to the surface on which the display panel is positioned.

Compared to the light emitting element 300, the opening of the first organic layer 251 is expanded outward by a certain distance D1, which is convenient to leave a space for the transfer apparatus 600 (such as a seal) to hold the light emitting element 300a and an alignment space between the light emitting element 300a and the second electrode portion 520.

When the first opening OP1 expands outward compared to the light emitting element 300, the connection portion 420 is exposed, which brings about the problem of increased reflectivity. Therefore, the distance D1 cannot be too large. As an example, the distance D1 between the light emitting element 300 and the edge of the first opening OP1 is to less than 10 microns.

The distance D1 between the light emitting element 300 and the edge of the first opening OP1 may be in the range from 2 microns to 7 microns.

The height of the first organic layer 251 may be less than that of the light emitting element 300 to facilitate the realization of the transfer of the light emitting element.

The drive substrate 200 includes a drive circuit layer 220, a planarization layer 230 and a connection portion 240. The planarization layer 240 is positioned between the drive circuit layer 220 and the connection portion 240. The connection portion 240 is positioned between the planarization layer 230 and the first organic layer 251. The first opening OP1 of the first organic layer 251 exposes the connection portion 240.

The drive circuit layer 220 includes a thin film transistor TFT, and the connection portion 240 includes a first connection portion 241, and the first connection portion 241 passes through the contact via CH of the planarization layer 230 and the thin film transistor TFT. The contact via CH is not overlapped with the first opening OP1 of the first organic layer 251, that is, the contact via CH is arranged away from the light emitting element setting area.

The planarization layer 230 is provided with a fourth opening. The fourth opening is overlapped with the pixel light-transmitting area PTA. The first organic layer 251 covers the sidewall 230s of the fourth opening of the planarization layer 230 for shielding light and reducing reflection.

The first film layer 250 further includes a protective layer 252 covering the sidewall of the first opening OP1 and the sidewall of the third opening OP3 of the first organic layer 251.

The protective layer 252 is provided with a fifth opening. The fifth opening is positioned in the pixel light-transmitting area PTA. The shape of the fifth opening is a rectangle with four corners removed, such as a rounded rectangle, as shown in the opening shape 252OP2 of the protective layer 252 in FIG. 33. This solution can improve the situation where holes appear in the first organic layer or holes appear in the protective layer caused by the high level difference at the edge of the pixel light-transmitting area PTA, and the resulted problems such as penetration of the stripping solution and over-etching of the four corners.

The difference between FIG. 38 and FIG. 39 is that the first organic layer 251 is further included between the first electrode 321 and the second electrode 322 in FIG. 38, while the first organic layer 251 may not be provided between the first electrode 321 and the second electrode 322 in FIG. 39. As such, a protective layer may not be provided between the first electrode 321 and the second electrode 322, which is beneficial to the release of the gas generated in the first organic layer 251 in the subsequent high temperature process. Otherwise, there may be a problem of swelling and cracking of the first organic layer.

As shown in FIG. 40, the drive substrate 200 includes a redundant electrode Pre. Since no eutectic process occurs, the redundant electrode Pre may be the second electrode portion 520. As an example, the redundant electrode Pre includes gold (Au).

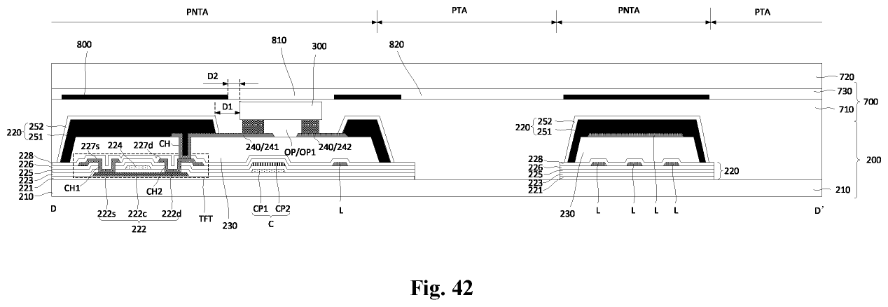

As shown in FIG. 41 and FIG. 42, the display panel further includes a package layer 700. The package layer 700 may include a package gule 710 and a cover plate 720. The package gule 710 covers the drive substrate 200 and is configured to package the light emitting element 300. The package gule 710 covers a side of the light emitting element 300, or also covers the upper surface of the light emitting element 300 at the same time.

It should be noted that, in other drawings that do not illustrate the package layer 700, the package layer 700 may be arranged over the drive substrate of the display panel, and the specific structure of the package layer 700 may be made reference to related drawings.

As shown in FIG. 42, the display panel further includes a black matrix 800. The black matrix 800 is positioned on a side of the package gule 710 away from the drive substrate 200. The black matrix 800 is provided with a first light-transmitting hole 810 and a second light-transmitting hole 820. The first light-transmitting hole 810 is positioned in the light emitting element setting area, and the second light-transmitting hole 820 is positioned in the pixel light-transmitting area PTA. The black matrix 800 may be in the shape of a mesh, and the first light-transmitting hole 810 and the second light-transmitting hole 820 are grids of the lack matrix 800. The black matrix 800 can reduce the reflectivity of the display panel while reducing the crosstalk between the light emitting elements 300.

Along a second direction, the distance D2 between the edge of the first light-transmitting hole 810 and the light emitting element 300 is less than the distance D1 between the edge of the first opening OP1 and the light emitting element 300, where the second direction is parallel to the plane where the display panel is positioned. With this arrangement, the problem of high reflectivity caused by the connection portion 240 positioned in the first opening OP1 can be further alleviated.

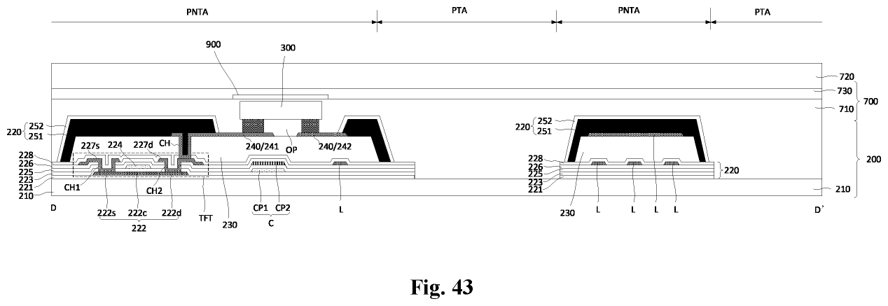

As shown in FIG. 42 and FIG. 43, the package layer 700 of the display panel further includes an adhesive layer 730. The adhesive layer 730 is positioned between the package gule 710 and the cover plate 720.

As shown in FIG. 43, the display panel further includes a color resist 900. The color resist 900 covers the light emitting element 300 for filtering light to improve light purity.

As shown in FIG. 44, the drive substrate further includes a redundant electrode Pre. Since no eutectic process occurs, the redundant electrode Pre may be the second electrode portion 520. As an example, the redundant electrode Pre includes gold (Au), and the color resist 900 covers the redundant electrode Pre, so as to reduce the influence of the redundant electrode Pre on the reflectivity of the display panel.

The color resist 900 includes a blue color resist 910, a green color resist 920 and a red color resist 930. The light emitting element 300 includes a blue light emitting element PB, a green light emitting element PG and a red light emitting element PR. The blue color resist 910 covers the blue light emitting element PB, the green color resist 920 covers the green light emitting element PG, and the red color resist 930 covers the red light emitting element PR. In other implementations, the red color resist may not be provided. First, the light extraction efficiency of the red light emitting element is low, and the addition of the red color resist further reduces the light extraction efficiency of the light emitting element. Second, most of the waveband of light reflected by the redundant electrode Pre or the connection portion 240 is waveband close to red light. Even if the red color resist is set, the anti-reflection effect is very limited.

The display panel 100 according to the embodiments of the present invention can be used for transparent display.

FIG. 45 is a schematic view of a display apparatus according to an embodiment of the present application. In FIG. 45, the display apparatus 1000 being a mobile phone is taken as an example. The display apparatus according to the embodiments of the present invention may include, but is not limited to, a device with a display function, such as a mobile phone, a tablet, a wall-mounted display screen, and a transparent display apparatus.

Finally it should be noted that, the above embodiments are only for illustrating technical solutions of the present application, rather than for limiting. Although the present application has been described in detail with reference to the foregoing embodiments, those of ordinary skill in the art should understand that it is still possible to modify the technical solutions recited in the foregoing embodiments, or perform equivalent replacements to some or all of the technical features thereof, however, these modifications or replacements do not make an essence of the corresponding technical solutions deviate from the scope of the technical solutions of the embodiments of the present application.

What is claimed is:

1. A display panel, comprising:
a drive substrate comprising a first film layer, the first film layer being provided with an opening;
a light emitting element positioned on the drive substrate and comprising a body portion and an electrode;
wherein the electrode comprises a first portion positioned in the opening.

2. The display panel according to claim 1, wherein
the first film layer comprises a first organic layer.

3. The display panel according to claim 2, wherein
the drive substrate further comprises a planarization layer and a connection portion, the planarization layer is positioned on a side of the first organic layer away from the light emitting element, the connection portion is positioned between the first organic layer and the planarization layer, and the first portion of the electrode is electrically connected to the connection portion;
the drive substrate further comprises a drive circuit layer, the drive circuit layer is positioned on a side of the planarization layer away from the first organic layer, and the drive circuit layer comprises a thin film transistor;
the connection portion comprises a first connection portion, and the thin film transistor is connected to the first connection portion;
the drive substrate further comprises a substrate and a passivation layer, the substrate is positioned on a side of the drive circuit layer away from the first organic layer, and the passivation layer is positioned between the drive circuit layer and the planarization layer.

4. The display panel according to claim 2, wherein
the first organic layer is provided with a first opening, and along a direction from the first film layer to the light emitting element, a sidewall of the first opening is inclined toward an interior of the first opening.

5. The display panel according to claim 2, wherein
the first organic layer comprises negative photoresist.

6. The display panel according to claim 2, wherein
the first organic layer comprises a light absorbing material.

7. The display panel according to claim 2, wherein
the first film layer further comprises a protective layer covering the first organic layer;
the first organic layer is provided with a first opening, the protective layer is provided with a second opening, and the second opening is overlapped with the first opening;
the protective layer covers a sidewall of the first opening of the first organic layer;
the protective layer comprises an inorganic layer.

8. The display panel according to claim 7, wherein
the protective layer comprises a silicon nitride layer and a silicon oxide layer that are stacked, and the silicon nitride layer is positioned between the silicon oxide layer and the first organic layer;
a thickness of the silicon nitride layer is less than a thickness of the silicon oxide layer.

9. The display panel according to claim 7, wherein
the second opening is larger than the first opening.

10. The display panel according to claim 6, wherein
the display panel comprises a pixel light-transmitting area and a non-light-transmitting area, and the non-light-transmitting area comprises a light emitting element setting area;
the first organic layer is provided with a first opening and a third opening, the first opening defines the light emitting element setting area, and the third opening defines the pixel light-transmitting area.

11. The display panel according to claim 10, wherein
along a first direction, a distance between the electrode of the light emitting element and an edge of the first opening is greater than zero;
wherein the first direction is parallel to a plane where the display panel is positioned;
the distance between the electrode of the light emitting element and the edge of the first opening is less than or equal to 10 microns;
L<10 microns.

12. The display panel according to claim 11, wherein
the drive substrate further comprises a drive circuit layer, a planarization layer and a connection portion;
the planarization layer is positioned between the drive circuit layer and the connection portion;
the connection portion is positioned between the planarization layer and the first organic layer;
the first opening of the first organic layer exposes the connection portion;
the drive circuit layer comprises a thin film transistor;
the connection portion comprises a first connection portion connected to the thin film transistor through a contact via of the planarization layer;
the contact via is not overlapped with the first opening.

13. The display panel according to claim 12, wherein
the planarization layer is provided with a fourth opening overlapped with the pixel light-transmitting area, and the first organic layer covers a sidewall of the fourth opening of the planarization layer.

14. The display panel according to claim 10, wherein
a height of the first organic layer is less than a height of the light emitting element.

15. The display panel according to claim 10, wherein
the first film layer further comprises a protective layer covering a sidewall of the first opening and a sidewall of the third opening;
the protective layer is provided with a fifth opening positioned in the pixel light-transmitting area, and a shape of the fifth opening is a rectangle with four corners removed.

16. The display panel according to claim 10, further comprising:
a package gule covering the drive substrate;
a black matrix positioned on a side of the package gule away from the drive substrate, the black matrix being provided with a first light-transmitting hole and a second light-transmitting hole, the first light-transmitting hole being positioned in the light emitting element setting area, and the second light-transmitting hole being positioned in the pixel light-transmitting area;
wherein along a second direction, a distance between an edge of the first light-transmitting hole and the light emitting element is less than a distance between an edge of the first opening and the light emitting element;
wherein the second direction is parallel to a plane where the display panel is positioned.

17. The display panel according to claim 10, further comprising:
a color resist covering the light emitting element;
wherein the drive substrate further comprises a redundant electrode positioned in the light emitting element setting area, and the color resist covers the redundant electrode.

18. The display panel according to claim 10, further comprising:
a color resist covering the light emitting element;
wherein the color resist comprises a blue color resist and a green color resist, the light emitting element comprises a blue light emitting element, a green light emitting element and a red light emitting element, the blue color resist covers the blue light emitting element, and the green color resist covers the green light emitting element.

19. A method for forming a display panel, comprising:
forming a first film layer of a drive substrate, the first film layer being provided with an opening;
forming a photoresist layer, the photoresist layer being positioned on a side of the first film layer;
forming a photoresist pattern, the photoresist pattern having a through hole overlapped with the opening;
forming an electrode layer, the electrode layer comprising a first electrode portion and a second electrode portion, the first electrode portion covering the photoresist pattern, and the second electrode portion comprising a portion positioned in the opening;
removing the photoresist pattern and the first electrode portion;
providing a light emitting element and transferring the light emitting element over the drive substrate, wherein the light emitting element comprises a body portion and a bonding electrode;
bonding the light emitting element to the second electrode portion, so that the bonding electrode and the second electrode portion form an electrode of the light emitting element.

20. A display apparatus comprising a display panel, wherein the display panel comprises:
a drive substrate comprising a first film layer, the first film layer being provided with an opening;
a light emitting element positioned on the drive substrate and comprising a body portion and an electrode;
wherein the electrode comprises a first portion positioned in the opening.
